(19) United States
(12) Patent Application Publication
(10) Pub. No.: US 2015/0221877 A1
(43) Pub. Date: Aug. 6, 2015

(54) TRANSITION METAL COMPLEXES COMPRISING SYMMETRIC TETRADENTATE LIGANDS

(71) Applicant: SOLVAY SA, Brussels (BE)

(72) Inventors: Luisa De Cola, Strasbourg (FR); Sebastian Duck, Munster (DE); Robert Cysewski, Pozman (PL); Maria Dolores Galvez Lopez, Murcia (ES); Jean-Pierre Catinat, Waudrez (BE)

(21) Appl. No.: 14/424,660

(22) PCT Filed: Aug. 22, 2013
(86) PCT No.: PCT/EP2013/067457

§ 371 Date: Feb. 27, 2015

(30) Foreign Application Priority Data
Aug. 31, 2012 (EP) 12182638.2
Sep. 28, 2012 (EP) 12186573.7

(51) Int. Cl. H01L 51/00; C09K 11/06; C07F 15/00

(52) U.S. Cl. CPC H01L 51/0085; C07F 15/0033; C09K 11/06; C09K 2211/185; H01L 51/5024

(57) ABSTRACT

Light emitting transition metal complexes comprising sub-units based on symmetric tetradentate ligands.

The present invention relates to light emitting transition metal complexes comprising symmetric tetradentate ligands and their use for the manufacture of organic electronic devices.

US 2005/170206 discloses organic light emitting devices comprising transition metal complexes based on multidentate ligands. Symmetric tetradentate ligands wherein two 2-phenylpyridine ligand units are connected via a linker are mentioned. This reference mentions that multidentate ligands should improve the kinetic stability of the transition metal complexes manufactured using same compared to isolated bidentate ligands.

WO 2008/096609 discloses carbene ligand units suitable for manufacturing transition metal complexes with two identical bidentate carbene ligand units being connected through an alkylene bridge.

US 2008/286605 discloses a symmetrical N, N′, O, O′ dianionic tetradentate ligand resulting from the deprotonation of 2,2′-(2,2′-bipyridine-6,6′-diyl)diphenol and transition metal complexes derived therefrom (cpd. D-29, page 48).

WO 2006/061182 discloses platinum complexes with symmetrical tetradentate ligands which are composed of two identical bidentate ligand units linked through a linker.

US 2010/0171417 discloses platinum complexes with tetradentate ligands comprising two identical or two different bidentate ligand units as phosphorescent materials in combination with certain charge transport materials useful in the manufacture of organic electronic devices.

Today, various light-emitting devices are under active study and development, in particular those based on electroluminescence (EL) from organic materials.

As a first example, light emitting electrochemical cells (often referred to as LEEC or LEO) may be mentioned. LEECs are solid state devices which generate light from an electric current. LEECs are usually composed of two metal electrodes connected by an organic semiconductor containing mobile ions.

Aside from the mobile ions, the structure of LEECs is similar to a second group of light emitting organic electronic devices which are commonly referred to as organic light emitting diodes (OLEDs).

In the contrast to photoluminescence, i.e. the light emission from an active material as a consequence of optical absorption and relaxation by radiative decay of an excited state, electroluminescence (EL) is a non-thermal generation of light resulting from the application of an electric field to a substrate. In this latter case, excitation is accomplished by recombination of charge carriers of opposite signs (electrons and holes) injected into an organic semiconductor in the presence of an external circuit.

A simple prototype of an organic light-emitting diode (OLED), i.e. a single layer OLED, is typically composed of a thin film of an active organic material which is sandwiched between two electrodes, one of which needs to have a degree of transparency sufficient in order to observe light emission from the organic layer.

If an external voltage is applied to the two electrodes, charge carriers, i.e. holes, at the anode and electrons at the cathode are injected to the organic layer beyond a specific threshold voltage depending on the organic material applied. In the presence of an electric field, charge carriers move through the active layer and are non-radiatively discharged when they reach the oppositely charged electrode. However, if a hole and an electron encounter one another while drifting through the organic layer, excited singlet (anti-parallel spin) and triplet (parallel spin) states, so-called excitons, are formed. Light is thus generated in the organic material from the decay of molecular excited states (or excitons). For every three triplet excitons that are formed by electrical excitation in an OLED, only one state with antiparallel spin (S=0) singlet exciton is created.

Many organic materials exhibit fluorescence (i.e. luminescence from a spin—allowed process) from singlet excitons: since this process occurs between states of same spin multiplicity it may be very efficient. On the contrary, if the spin multiplicity of an exciton is different from that of the ground state, then the radiative relaxation of the exciton is forbidden and luminescence will be slow and inefficient. Because the ground state is usually a singlet decay from a triplet is spin forbidden (different spin multiplicity) and efficiency of EL is very low. Thus the energy contained in the triplet states is mostly wasted.

Phosphorescence emission is a phenomenon of light emission in the relaxation process between two states of different spin multiplicity, often between a triplet and a singlet, but because the relaxation process is normally conducted by thermal deactivation, it is in many cases not possible to observe phosphorescence emission at room temperature. Characteristically, phosphorescence may persist for up to several seconds after excitation due to the low probability of the transition, in contrast to fluorescence which originates in the rapid decay.

The theoretical maximum internal quantum efficiency of light-emitting devices comprising light-emitting materials based on an emission phenomenon in the relaxation process from a singlet excited state, (i.e. fluorescence emission), is at maximum 25%, because in organic EL devices the ratio of the singlet to the triplet state in the excited state of light-emitting materials is always about 25:75. By using phosphorescence emission (emission from triplet states) this efficiency could be raised to the theoretical limit of 100%, thereby significantly increasing the efficiency of the EL device.

As mentioned above, it is difficult to get phosphorescence emission from an organic compound because of low probability of intersystem crossing and concurrent thermal deactivation of the triplet relaxation process. However, it has been found that certain “organic” compounds containing a complexed heavy metal show phosphorescence emission because of the spin-orbit interaction resulting from the heavy metal atom effect.

The wavelength of the light emitted is governed by the structure and the combination of ligands in the transition metal complex.

One of the challenges still to be satisfactorily solved in organic light emitting devices is the availability of suitable transition metal complexes providing sufficient stability in operating devices on one hand and desired photoactive properties on the other hand.

Accordingly there is still a need for phosphorescent transition metal complexes having improved stability, especially those emitting in the blue region, to obtain highly efficient and long term stable devices. Furthermore, to realize large area display and lighting applications at low cost, it is of interest to develop new emitters with sufficient solubility in suitable solvents to enable processing from solution, such as roll-to-roll printing, as the majority of known phosphorescent emitters are not soluble enough in organic solvents.

It was thus an object of the present invention to provide new transition metal complexes comprising tetradentate ligands useful in the manufacture of organic light emitting devices.

This object has been achieved with the transition metal complexes in accordance with claim 1 with a subunit comprising a symmetric tetradentate ligand.

Preferred embodiments of the present invention are set forth in the dependent claims and the detailed specification hereinafter.

The light emitting transition metal complexes in accordance with the present invention comprise a transition metal M with a coordination number equal to six and an atomic number of at least 40, preferably selected from Ir, Rh, Os, Re or Ru and particularly preferably Ir, and a subunit with a symmetric tetradentate ligand comprising two identical bidentate ligand units L and represented by general formula (1)

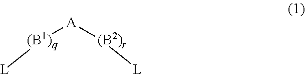

wherein q and r, which may be the same or different, are 0 or 1, preferably at least one of q and r being 1 and even more preferably both q and r being 1, the pending arms B¹ and B², which may be the same or different, are represented by general formula (2)

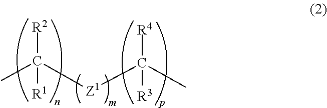

wherein Z¹ is a divalent group selected from the group consisting of —O—, —S—, —NR⁵—, —BR⁶—, —PR⁷—, —P(═O)R⁵—, —SiR⁹R¹⁰—, —N(R¹¹)—C(═O)—, —N═C(R¹²)—, —C(═O)—, —C═NR¹³—, —C(═S)— and —P(═S)(R¹⁴)—,
wherein R¹ to R¹⁴, which may be the same or different at each occurrence, are selected from hydrogen, halogen, NO₂, CN, NH₂, NHR′, N(R′)₂, B(OH)₂, B(OR′)₂, CHO, COOH, CONH₂, CON(R′)₂, CONHR′, SO₃H, C(═O)R′, P(═O)(R′)₂, S(═O)R′, S(═O)₂R′, P(R′)₃⁺, N(R′)₃⁺, OH, OR′, SR′ and alkyl, haloalkyl, aryl, aralkyl or heteroaryl groups with R′ being selected from hydrogen, alkyl, aralkyl, aryl and heteroaryl groups, n, m and p, independently of one another, are integers of from 0 to 8, the sum of n+m+p being at least 1, and
wherein the ligand unit L is represented by formula (3).

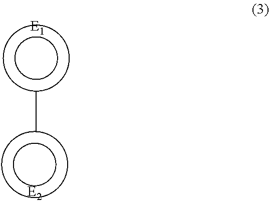

wherein

E₁ represents a nonmetallic atom group required to form a 5- or 6-membered heteroaromatic ring, optionally condensed with additional aromatic moieties or non aromatic cycles, said ring optionally having one or more substituents, optionally forming a condensed structure with the ring comprising E₂, and

E₂ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E₁, and wherein the ring E₁ is bound to the transition metal via a neutral heteroatom, preferably a nitrogen atom, and the ring E₂ is bound to the transition metal through a carbon atom having formally a negative charge or through a nitrogen atom having formally a negative charge and with the proviso that L is not 2-phenylpyridine and wherein

bivalent linking central scaffold A is selected from compounds of general formulae (4) to (7)

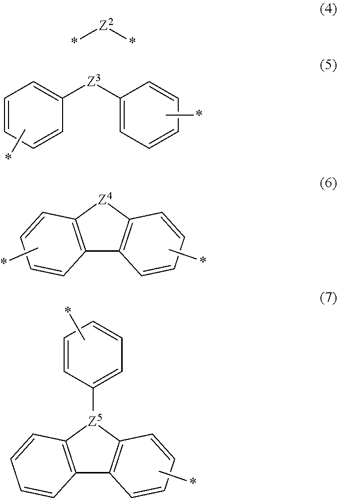

wherein the rings in formulae (5) to (7) may be unsubstituted or substituted with substituents R

Z² is CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te or a substituted or unsubstituted 5- or 6-membered carbocyclic, aromatic or heteroaromatic ring; preferably Z² is CR₂, RN, —O—, —S—, RB, RP, RP(O), SiR₂ or a substituted or unsubstituted 5- or 6-membered carbocyclic, aromatic or heteroaromatic ring.

In accordance with an embodiment of the present invention, Z² is preferably a substituted or unsubstituted 5- or 6-membered carbocyclic, aromatic or heteroaromatic ring (which may carry substituents other than hydrogen). The heterocyclic rings may comprise one or more heteroatoms, preferably selected from O, N, S, P and Si, with O, N and S being particularly preferred.

In accordance with another preferred embodiment Z² is a substituted or unsubstituted 5- or 6-membered carbocyclic, aromatic or heteroaromatic ring (which may carry substituents other than hydrogen) selected from the group consisting of

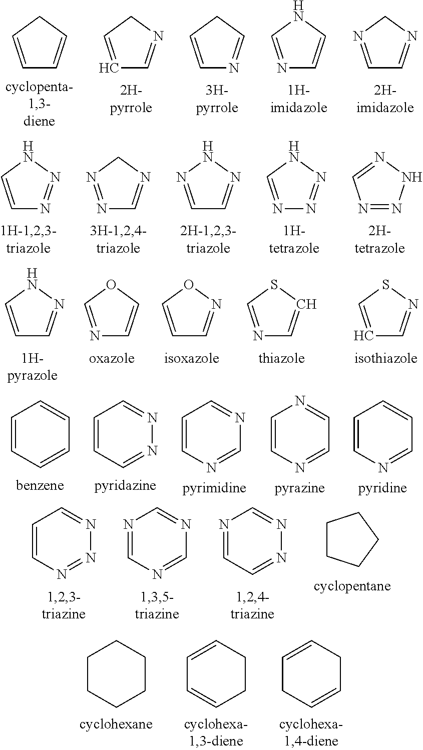

6-membered carbocyclic, aromatic or heteroaromatic rings being preferred, in particular Z² is a cyclohexane ring, a benzene ring, a pyridine ring, a pyrimidine ring, a 1,3,5- or 1,2,3-triazine ring.

Z³ and Z⁴ are CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te, preferably Z³ and Z⁴ are CR₂, NR, —O—, —S—, RB, RP, RP(O) or SiR₂; particularly preferred Z³ is CR₂, NR, RB, RP, RP(O) and SiR₂, particularly preferred Z⁴ is CR₂, NR, O, S and SiR₂.

Z⁵ is CR, N, RN⁺, B, RB⁻, P, P(O), SiR, Al, RAl⁻, As, As(O), Sb, Sb(O), Bi, Bi(O), preferably CR, N, B, P, P(O) and SiR and

R, which may be the same or different at each occurrence, is selected from the group consisting of hydrogen, alkyl, haloalkyl, aralkyl, aryl and heteroaryl.

Preferred alkyl groups R which includes cycloalkyl groups are C₁ to C₂₀, preferably C₁ to C₁₀ and particularly preferably C₁ to C₆ alkyl groups, most preferred being methyl, ethyl, i-propyl, n-propyl, n-, i- and t-butyl, cyclopentyl, cyclohexyl and C₁₀ adamantyl groups.

Preferred haloalkyl groups R are based on the preferred alkyl groups defined above, wherein one or more of the hydrogen atoms have been replaced by one or more halogen atoms. Accordingly, preferred haloalkyl groups are based on C₁ to C₂₀, preferably C₁ to C₁₀ and particularly preferably C₁ to C₆ alkyl groups, most preferred being methyl, ethyl, i-propyl, n-propyl and n-, i- and t-butyl, cyclopentyl, cyclohexyl and C₁₀ adamantyl group.

Preferred aralkyl groups R comprise alkyl groups as defined before wherein one or more of the hydrogen atoms have been replaced by an aryl group, preferably as defined below. The total number of carbon atoms in the aralkyl groups is between 5 and 50, preferably between 6 and 35 and particularly preferred between 6 and 25 carbon atoms. One or more carbon atoms in the aryl rings may be replaced by a heteroatom, e.g. N, O or S.

Preferred aryl groups R are 5- or 6-membered aromatic ring systems, which may carry one or more substituents other than hydrogen. Two or more rings may be annealed to form condensed structures or two and more aryl groups may be connected through a chemical bond. Examples for preferred aryl groups are phenyl, naphthyl, biphenyl, triphenyl and anthracenyl.

Preferred heteroaryl groups R are ring systems as described above for aryl rings wherein one or more of the ring carbon atoms has been replaced by a heteroatom, preferably selected from N, O and S. Preferred heteroaryl groups R are based on rings selected from the group consisting of

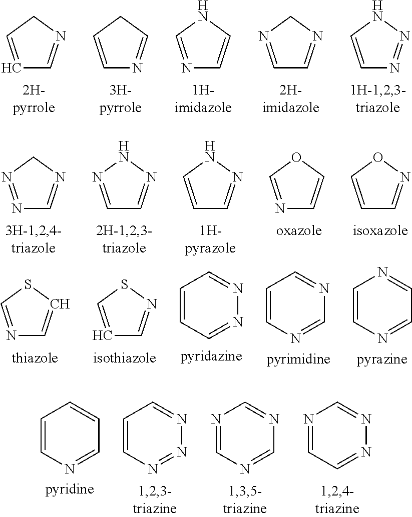

Preferred aryl and heteroaryl ring systems R comprise of from 1 to 50, preferably of from 1 to 30 and particularly preferably of from 1 to 20 carbon atoms.

In yet another preferred embodiment, central scaffold A comprises a moiety which is known to make part of a host or a hole or electron transport materials used in OLEDs. Such preferred moieties are pyridine, pyrimidine, triazine, carbazole, dibenzofuran and dibenzothiophene heteroaryl ring. Other preferred moieties correspond to triphenylamine, triphenylsilyl, triarylboron and phosphine oxide group.

In the formulae (4) to (7) given above * denotes the two bonding sites of the bivalent central scaffold A through which the ligands L are bonded either directly or through arm units B¹ and/or B² (q and r both being 1 in this case).

A is particularly preferably a CR₂, RN, —O—, —S—, RB, RP, RP(O), SiR₂ group or a five or six membered carbocyclic, aromatic or heteroaromatic ring in which the arm substituents B¹ and/or B², if present, may be attached to the ring in any combination of positions, A represents particularly preferably CR₂, RN, RB, RP(O), SiR₂ group or a five or six membered ring system selected from the group consisting of

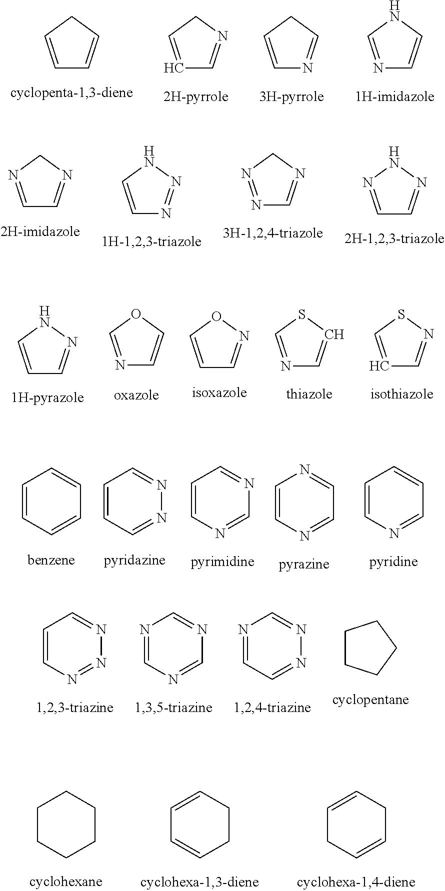

In accordance with a further preferred embodiment A is a six membered carbocyclic, aromatic or heteroaromatic ring, in particular a cyclohexane ring, a benzene ring, a pyridine ring, a pyrimidine ring, a 1,3,5- or 1,2,3-triazine ring to which arm units B¹ and/or B² (if present) or the ligand units L directly are preferably bound in 1,3 meta position to each other.

In still another preferred embodiment, arm units B¹ and/or B² (if present) or the ligand units L directly are preferably bound in 1,4 para position to each other of an aryl or heteroaryl ring, in particular a cyclohexane ring, a benzene ring, a pyridine ring, a pyrimidine ring, a 1,3,5- or 1,2,3-triazine ring.

The bonding of arm units B¹ and/or B² (if present) or directly of ligand units L in 1,2 ortho position to each other is less preferred compared to 1,3 and 1,4-bonding for sterical reasons.

In accordance with another preferred embodiment, bivalent central scaffold A is selected from formula (5) in which the two ligand units L may be attached either directly or through arm units B¹ and/or B² to the phenyl rings in any combination of positions, as shown in the formula. In accordance with a further preferred embodiment, A is selected from formula (5) wherein the two ligand units L are attached to the phenyl rings either directly or through arm units B¹ and/or B² in para positions to the Z³ atom.

In accordance with another preferred embodiment, bivalent central scaffold A is selected from formulae (6) to (7) in which the two ligand units L may be attached either directly or through arm units B¹ and/or B² to the benzene rings in any combination of positions, as shown in the formulae. In accordance with a further preferred embodiment, A is selected from formulae (6) to (7) wherein the two ligand units L are attached to the benzene rings either directly or through arm units B¹ and/or B² in para positions to the Z⁴ and Z⁵ atoms.

The arm units B¹ and/or B² may be any divalent bridging group represented by formula (2) given above.

Preferred groups B¹ and/or B² are selected from alkylene groups having of from 1 to 8 carbon atoms, i.e. groups of formula (2) wherein m and p are zero and n is an integer of from 1 to 8, particularly preferred from alkylene groups having of from 2 to 4 carbon atoms.

In certain cases it has proven to be advantageous if, in addition to an alkylene chain an element Z¹ is present (i.e. m is 1), which in this case is preferably —O—, —S—, —NR⁵—, —BR⁶—, —PR⁷—, —P(═O)R⁸—, —SiR⁹R¹⁰—, —N(R¹¹)—C(═O)—, —N═C(R¹²)—, —C(═O)—, —C═NR¹³— with R⁵ to R¹³ as defined hereinabove, in particular —O—, —S—, —NR⁵—, —N(R¹¹)—C(═O)—, —N═C(R¹²)—, —C(═O)—, —C═NR¹³— with R⁵ to R¹³ as defined hereinabove.

In accordance with another preferred embodiment B¹ and/or B² represents a group of formula (2) with n being an integer of from 1 to 8, m being 1 and p being an integer of from 1 to 8, i.e. wherein two alkylene groups are separated by a group Z¹ as defined above.

In accordance with another embodiment arm units B¹ and/or B² comprise a structural element —CH₂—NH—, —CH₂—CH₂—NH—, —CH₂—N(CH₃)—, —CH₂—NH—CH₂—, —N(CH₃)—CH₂, —CH₂—CH₂—NH—C(═O)—, —CH₂—NH—C(═O)— and the equivalent structural elements wherein one or more of the hydrogen atoms attached to carbon atoms are replaced by methyl or ethyl.

The sum of n+m+p is at least 1, preferably n and p independently of one another are integers of from 0 to 8, preferably of from 0 to 4 and m is preferably 0 or 1.

For the purposes of the present invention, tetradentate ligands which involve ligand units L which are identical in structure and composition but are bound to central scaffold A or arm-units B¹ and/or B² through different positions are deemed to be symmetric in accordance with the present invention.

The ligand units L may be bound to arm units B¹ and/or B², if present, or central scaffold A through any position or in any manner which does not interfere with those positions through which the bidentate ligand units L are bound to the transition metal in the light emitting transition metal complexes in accordance with the present invention.

In principle any ligand unit L described in the prior art as bidentate ligand for transition metal complexes and pertaining to formula (3) may be present in the light emitting transition metal complexes in accordance with the present invention. Thus, reference may be made to the prior art documents describing such ligands.

In accordance with the present invention E₁ is bound to the transition metal through a neutral heteroatom, preferably a nitrogen atom, and ring E₂ is bound to the transition metal through a carbon atom having formally a negative charge or through a nitrogen atom having formally a negative charge with the proviso that L is not 2-phenylpyridine.

Ring E₁ is a 5 or 6-membered heteroaryl ring containing at least one donor nitrogen atom. Said ring may be un-substituted or substituted by substituents selected from the group consisting of halogen, NO₂, CN, NH₂, NHR¹⁵, N(R¹⁵)₂, B(OH)₂, B(OR¹⁵)₂, CHO, COOH, CONH₂, CON(R¹⁵)₂, CONHR¹⁵, SO₃H, C(═O)R¹⁵, P(═O)(R¹⁵)₂, S(═O)R¹⁵, S(═O)₂R¹⁵, P(R¹⁵)₃⁺, N(R¹⁵)₃⁺, OH, OR¹⁵, SH, Si(R¹⁵)₃, and alkyl, haloalkyl, alkenyl, alkynyl, arylalkyl, aryl and heteroaryl groups with R¹⁵ being selected from hydrogen, alkyl, aralkyl, aryl and heteroaryl groups and/or may form an annealed ring system with other rings selected from cycloalkyl, aryl and heteroaryl rings. Heteroaryl substituents may be preferably un-substituted or substituted carbazolyl or un-substituted or substituted dibenzofuranyl.

More particularly E₁ is a heteroaryl ring derived from the heteroarenes group consisting of 2H-pyrrole, 3H-pyrrole, 1H-imidazole, 2H-imidazole, 4H-imidazole, 1H-1,2,3-triazole, 2H-1,2,3-triazole, 1H-1,2,4-triazole, 1H-pyrazole, 1H-1,2,3,4-tetrazole, oxazole, isoxazole, thiazole, isothiazole, 1,2,3-oxadiazole, 1,2,5-oxadiazole, 1,2,3-thiadiazole, 1,2,5-thiadiazole, pyridazine, pyridine, pyrimidine, pyrazine, 1,2,3-triazine, 1,2,4-triazine, 1,3,5-triazine, 1,2,3,4-tetrazine, 1,2,4,5-tetrazine and 1,2,3,5-tetrazine rings, which may be unsubstituted or substituted as defined above.

In accordance with a further preferred embodiment ring E₂ is selected from the group consisting of substituted or un-substituted C₅-C₃₀ aryl and substituted or un-substituted C₂-C₃₀ heteroaryl groups, which E₂ group may be un-substituted or substituted by substituents selected from the group consisting of halogen, NO₂, CN, NH₂, NHR¹⁵, N(R¹⁵)₂, B(OH)₂, B(OR¹⁵)₂, CHO, COOH, CONH₂, CON(R¹⁵)₂, CONHR¹⁵, SO₃H, C(═O)R¹⁵, P(═O)(R¹⁵)₂, S(═O)R¹⁵, S(═O)₂R¹⁵, P(R¹⁵)₃⁺, N(R¹⁵)₃⁺, OH, OR¹⁵, SH, Si(R¹⁵)₃, and alkyl, haloalkyl, alkenyl, alkynyl, arylalkyl, aryl and heteroaryl groups as defined hereinabove with R¹⁵ being selected from hydrogen, alkyl, aralkyl, aryl and heteroaryl groups.

E₁ and E₂ may be linked through a divalent linking group or through a covalent bond, which has proved to be advantageous in certain cases.

In the following a number of preferred embodiments of the present invention will be described in more detail.

According to a first preferred embodiment ligand unit L is represented by formulae (8) to (10)

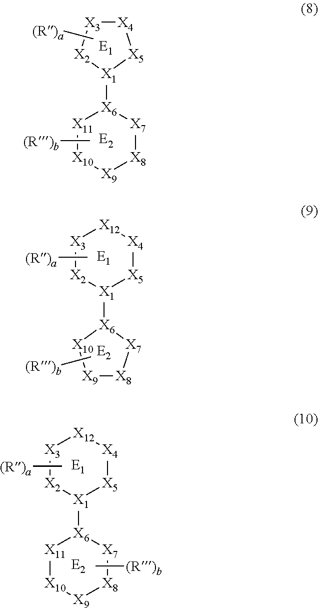

wherein

X₅ is a neutral nitrogen atom via which the 5- or 6-membered heteroaromatic ring E₁ is bound to the metal, X₇ is a carbon atom having formally a negative charge or a nitrogen atom having formally a negative charge via which the 5- or 6-membered aromatic or heteroaromatic ring E₂ is bound to the metal,

X₁, X₂, X₃, X₄, X₆, X₈, X₉, X₁₀, X₁₁, X₁₂ are independently from one another a carbon atom or a heteroatom, preferably a nitrogen atom.

R″ and R″″, which may be the same or different at each occurrence, are hydrogen, halogen, NO₂, CN, NH₂, NHR⁶¹, N(R⁶¹)₂, B(OH)₂, B(OR⁶¹)₂, CHO, COOH, CONH₂, CON(R⁶¹)₂, CONHR⁶¹, SO₃H, C(═O)R⁶¹, P(═O)(R⁶¹)₂, S(═o)R⁶¹, S(═O)₂R⁶¹, P(R⁶¹)₃⁺, N(R⁶¹)₃⁺, OR⁶¹, SR⁶¹, Si(R⁶¹)₃, a straight chain alkyl or alkoxy group having 1 to 20 carbon atoms or a branched or cyclic alkyl or alkoxy group with 3 to 20 carbon atoms, a haloalkyl group, a substituted or unsubstituted aromatic or heteroaromatic ring system having 5 to 50 ring atoms or a substituted or unsubstituted aryloxy, heteroaryloxy or heteroarylamino group having 5 to 50 ring atoms, two or more substituents R″ and R′″, either on the same or on different rings may define a further mono- or polycyclic, aliphatic or aromatic ring system with one another or with a substituent R⁶¹,

R⁶¹, which may be the same or different on each occurrence, may be hydrogen or a straight chain alkyl or alkoxy group having 1 to 20 carbon atoms or a branched or cyclic alkyl or alkoxy group with 3 to 20 carbon atoms, a substituted or unsubstituted aromatic or heteroaromatic ring system having 5 to 50 ring atoms or a substituted or unsubstituted aryloxy, heteroaryloxy or heteroarylamino group having 5 to 50 ring atoms, and a and b, independently from one another represent an integer in the range of from 0 to 3.

The two ligand units L, independently from each other, may be bound to arm-units B¹ and/or B², if present, or to central scaffold A, through any position, including those from the R″ and R′″ substituents, or in any manner which does not interfere with those positions through which the bidentate ligand units L are bound to the transition metal.

The ligand units L are preferably bound to arm-units B¹ and/or B², if present, or to central scaffold A, through their 6-membered E₁ and E₂ rings via those atoms which are located in para position to the E₁-E₂ bond (X₁-X₆ bond), which correspond to X₉ atom in formula (8), to X₁₂ atom in formula (9) and to X₉ and X₁₂ atoms in formula (10). The ligand units L are further preferably bound through their 6-membered E₁ and E₂ rings via the atom which is located in meta position to the E₁-E₂ bond (X₁-X₆ bond), which correspond to X₁₀ atom in formula (8), to X₃ atom in formula (9) and to X₃ and X₁₀ atoms in formula (10). Still another preferred linkage positions are those from 5-membered E₁ and E₂ rings corresponding to X₃ and X₄ atoms in formula (8) and to X₉ atom in formula (9).

In accordance with another preferred embodiment, ligand units L are selected from the group consisting of phenylimidazole derivatives, phenylpyrazole derivatives, phenyltriazole derivatives, phenyltetrazole derivatives, 2-(1H-1,2,4-triazol-5-yl)pyridine derivatives, 2-(1H-pyrazol-5-yl)pyridine derivatives, phenylpyridine derivatives other than 2-phenylpyridine, phenylquinoline derivatives and phenylisoquinoline derivatives.

In yet another preferred embodiment of the present invention, ligand unit L is selected from the group consisting of compounds of formulae (11) to (15) which pertain to general formula (8)

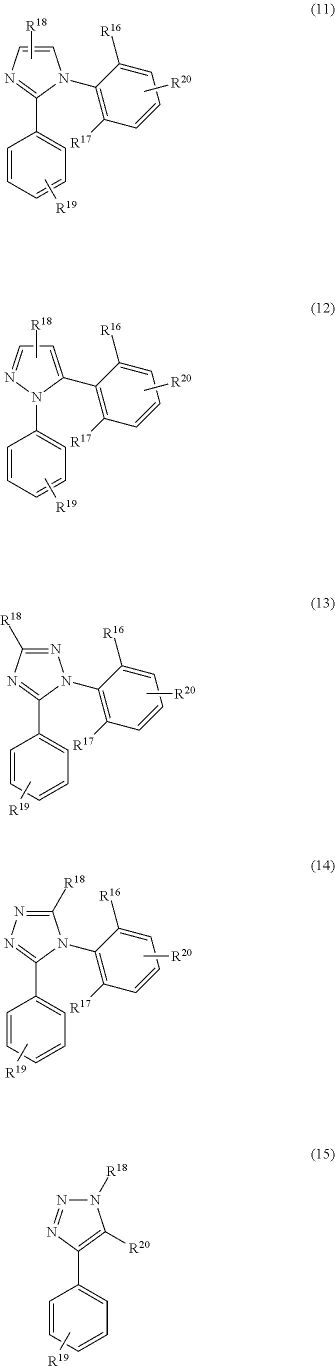

wherein R¹⁶ and R¹⁷ may be the same or different and are groups other than hydrogen, preferably alkyl, haloalkyl, cycloalkyl, aryl and heteroaryl group, and more preferably alkyl and haloakyl group, and wherein R¹⁸ to R²⁰ may be the same or different and may be selected from the group consisting of hydrogen, halogen, NO₂, CN, NH₂, NHR²¹, N(R²¹)₂, B(OH)₂, B(OR²¹)₂, CHO, COOH, CONH₂, CON(R²¹)₂, CONHR²¹, SO₃H, C(═O)R²¹, P(═O)(R²¹)₂, S(═O)R²¹, S(═O)₂R²¹, P(R²¹)₃⁺, N(R²¹)₃⁺, OH, OR²¹, SR²¹, Si(R²¹)₃, and alkyl, haloalkyl, alkenyl, alkynyl, arylalkyl, aryl and heteroaryl groups, with R²¹ being selected from hydrogen, alkyl, aralkyl, aryl and heteroaryl groups.

In accordance with yet another preferred embodiment, ligand unit L is selected from the group consisting of compounds of formulae (16) to (25) which pertain to general formulae (11) and (12) and of compound of formula (26)

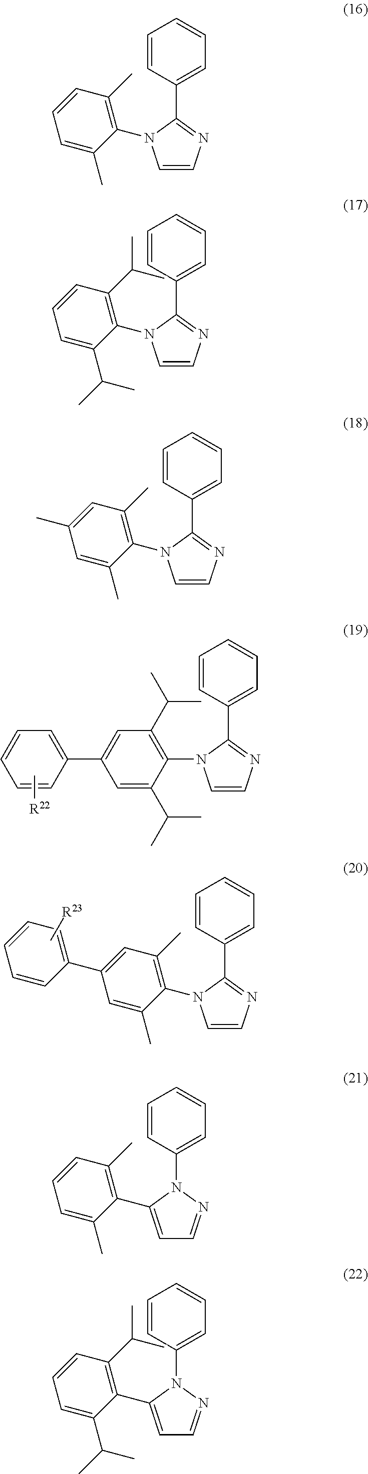

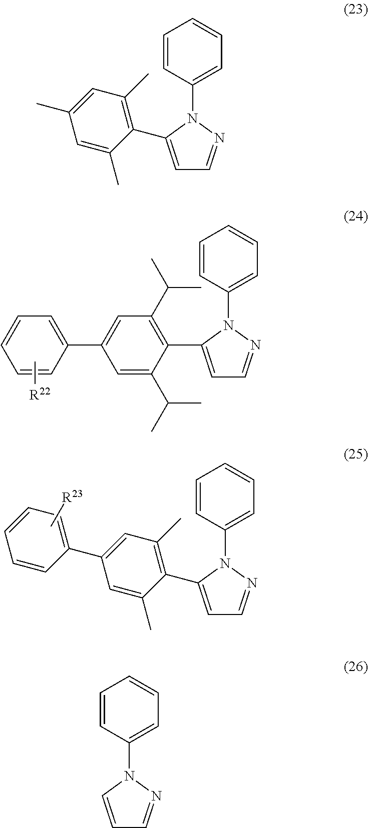

wherein R²² and R²³, independent of one another, are selected from hydrogen, halogen, NO₂, CN, NH₂, NHR²⁴, N(R²⁴)₂, B(OH)₂, B(OR²⁴)₂, CHO, COOH, CONH₂, CON(R²⁴)₂, CONHR²⁴, SO₃H, C(═O)R²⁴, P(═O)(R²⁴)₂, S(═O)R²⁴, S(═O)₂R²⁴, P(R²⁴)₃⁺, N(R²⁴)₃⁺, OH, OR²⁴, SR²⁴, Si(R²⁴)₃, and alkyl, haloalkyl, alkenyl, alkynyl, arylalkyl, aryl and heteroaryl groups, with R²⁴ being selected from hydrogen, alkyl, aralkyl, aryl and heteroaryl groups.

Further preferably, ligand unit L is selected from compounds of the general formulae (27) and (28) which pertain to general formula (9)

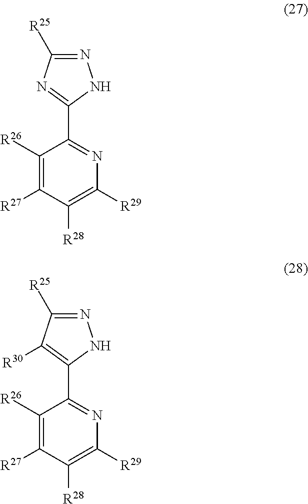

wherein R²⁵ to R³⁰ may be the same or different at each occurrence and may be selected from the group consisting of hydrogen, halogen, NO₂, CN, NH₂, NHR³¹, N(R³¹)₂, B(OH)₂, B(OR³¹)₂, CHO, COOH, CONH₂, CON(R³¹)₂, CONHR³¹, SO₃H, C(═O)R³¹, P(═O)(R³¹)₂, S(═O)R³¹, S(═O)₂R³¹, P(R³¹)₃⁺, N(R³¹)₃⁺, OH, OR³¹, SR³¹, Si(R³¹)₃, and alkyl, haloalkyl, alkenyl, alkynyl, arylalkyl, aryl and heteroaryl groups, with R³¹ being selected from hydrogen, alkyl, aralkyl, aryl and heteroaryl groups.

In accordance with still another preferred embodiment ligand unit L is selected from compounds of the general formulae (29) to (31) which pertain to general formula (10)

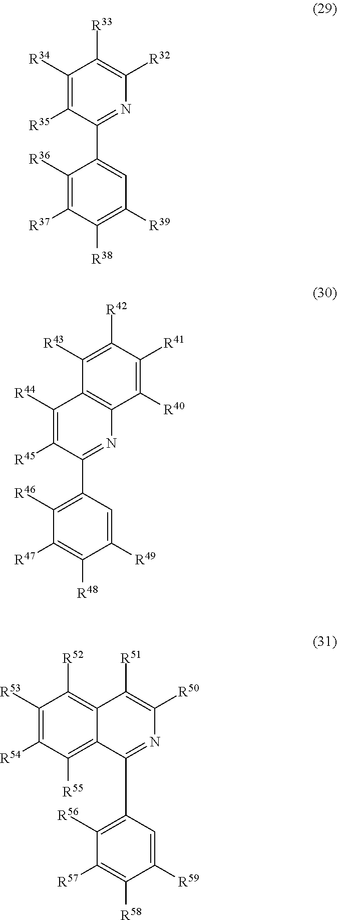

wherein R³² to R³⁹ may be the same or different at each occurrence and may be selected from the group consisting of hydrogen, halogen, NO₂, CN, NH₂, NHR⁶⁰, N(R⁶⁰)₂, B(OH)₂, B(OR⁶⁰)₂, CHO, COOH, CONH₂, CON(R⁶⁰)₂, CONHR⁶⁰, SO₃H, C(═O)R⁶⁰, P(═O)(R⁶⁰)₂, S(═O)R⁶⁰, S(═O)₂R⁶⁰, P(R⁶⁰)₃⁺, N(R⁶⁰)₃⁺, OH, OR⁶⁰, SR⁶⁰, Si(R⁶⁰)₃, and alkyl, haloalkyl, alkenyl, alkynyl, arylalkyl, aryl and heteroaryl groups, with R⁶⁰ being selected from hydrogen, alkyl, aralkyl, aryl and heteroaryl groups, and, provided that at least one of R³² to R³⁹ is different from hydrogen, and wherein R⁴⁰ to R⁵⁹ may be the same or different at each occurrence and may be selected from the group consisting of hydrogen, halogen, NO₂, CN, NH₂, NHR⁶⁰, N(R⁶⁰)₂, B(OH)₂, B(OR⁶⁰)₂, CHO, COOH, CONH₂, CON(R⁶⁰)₂, CONHR⁶⁰, SO₃H, C(═O)R⁶⁰, P(═O)(R⁶⁰)₂, S(═O)R⁶⁰, S(═O)₂R⁶⁰, P(R⁶⁰)₃⁺, N(R⁶⁰)₃⁺, OH, OR⁶⁰, SH, Si(R⁶⁰)₃, and alkyl, haloalkyl, alkenyl, alkynyl, arylalkyl, aryl and heteroaryl groups, with R⁶⁰ being selected from hydrogen, alkyl, aralkyl, aryl and heteroaryl groups.

Tetradentate ligands of formulae (L32) to (L45) are preferred ligands for subunits of the light emitting transition metal complexes of the present invention. For the sake of simplicity, central scaffold A has been chosen to represent a benzene ring and B¹ and B² are CH₂—CH₂ units which are linked to A in meta or para positions to each other in each of formulae L32 to L45; it is also possible, however, to choose A, B¹ and B² from the broader definitions given hereinbefore as well as the way the pending arms B¹ and B², if present, are linked to the central scaffold A as indicated hereinbefore. In the same way, for the sake of simplicity, it has been chosen to bind the pending arms B¹ and B² to the phenyl ring of the bidentate ligand units L in para or in meta position to the imidazole/pyrazole ring; it is also possible, however, to bind the bidentate ligand units L to pending arms B¹ and B², if present, or to central scaffold A through any position or in any manner which does not interfere with those positions through which the bidentate ligand units L of the symmetric tetradentate ligand are bound to the transition metal.

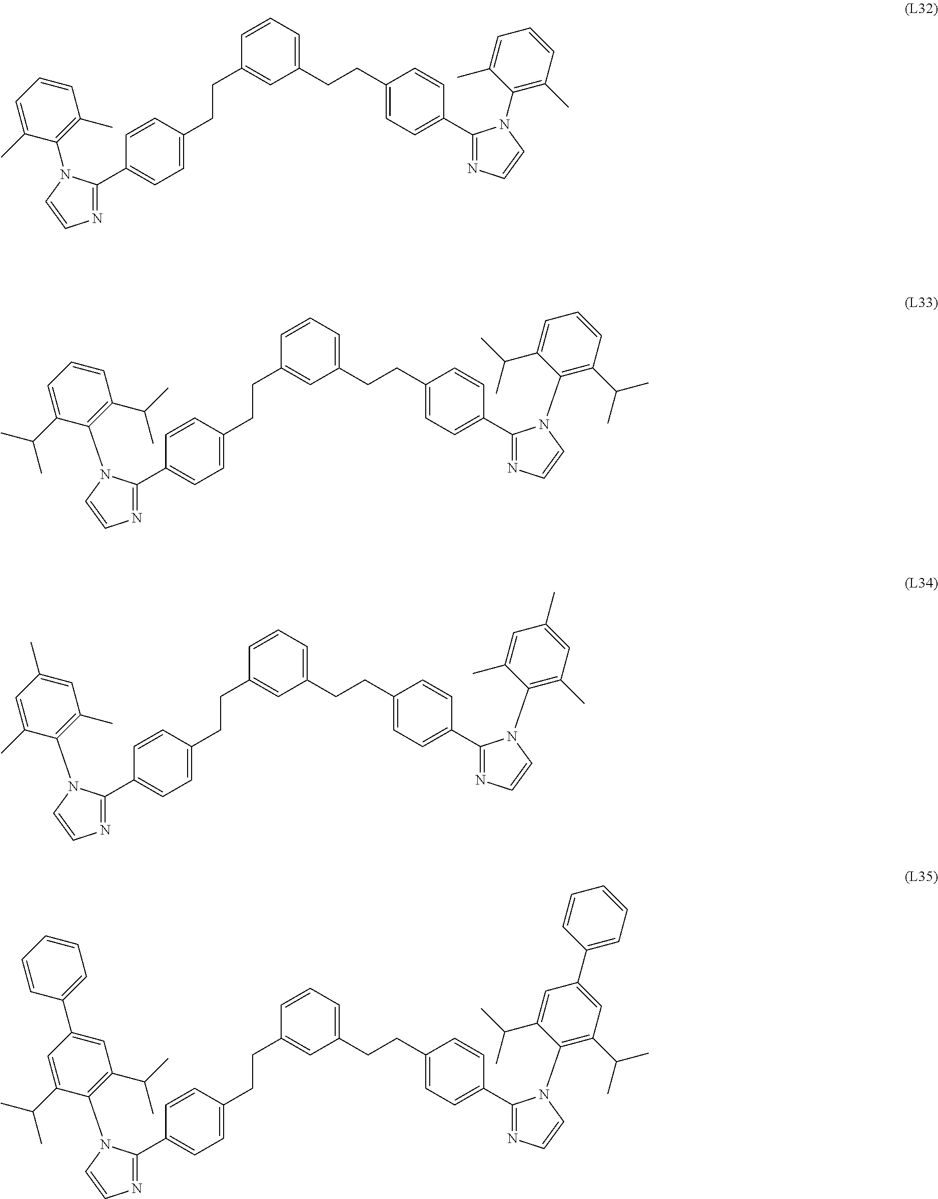

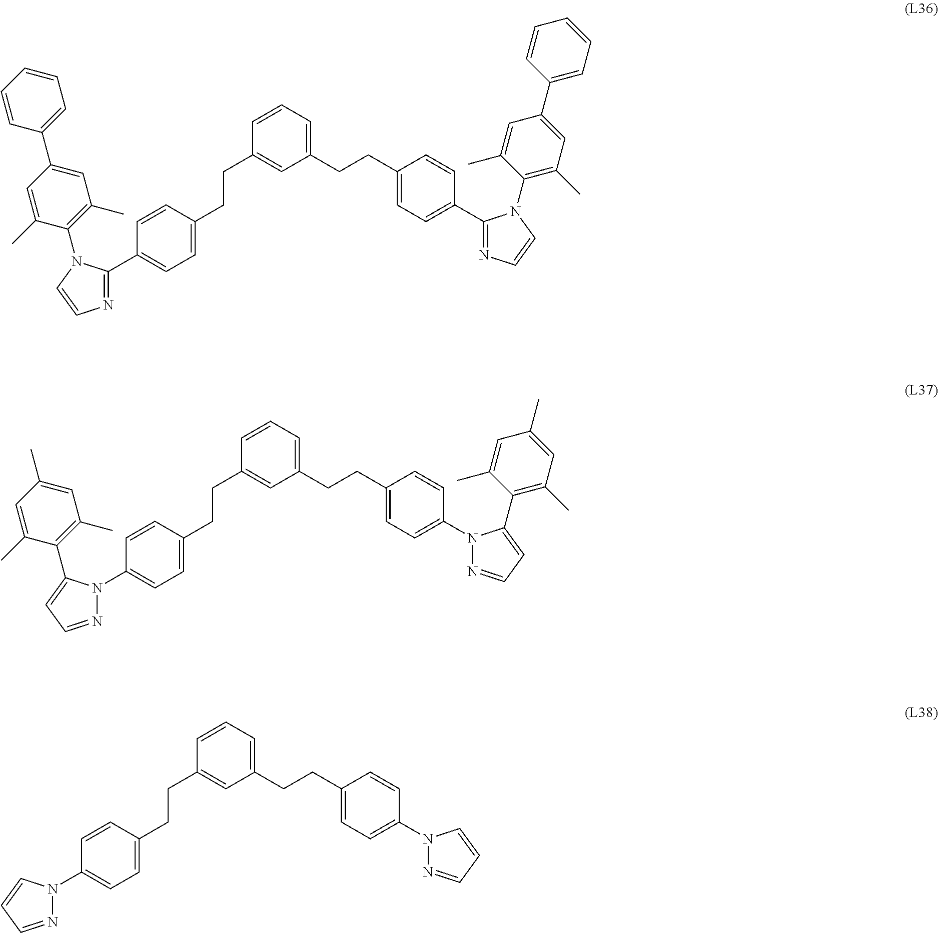

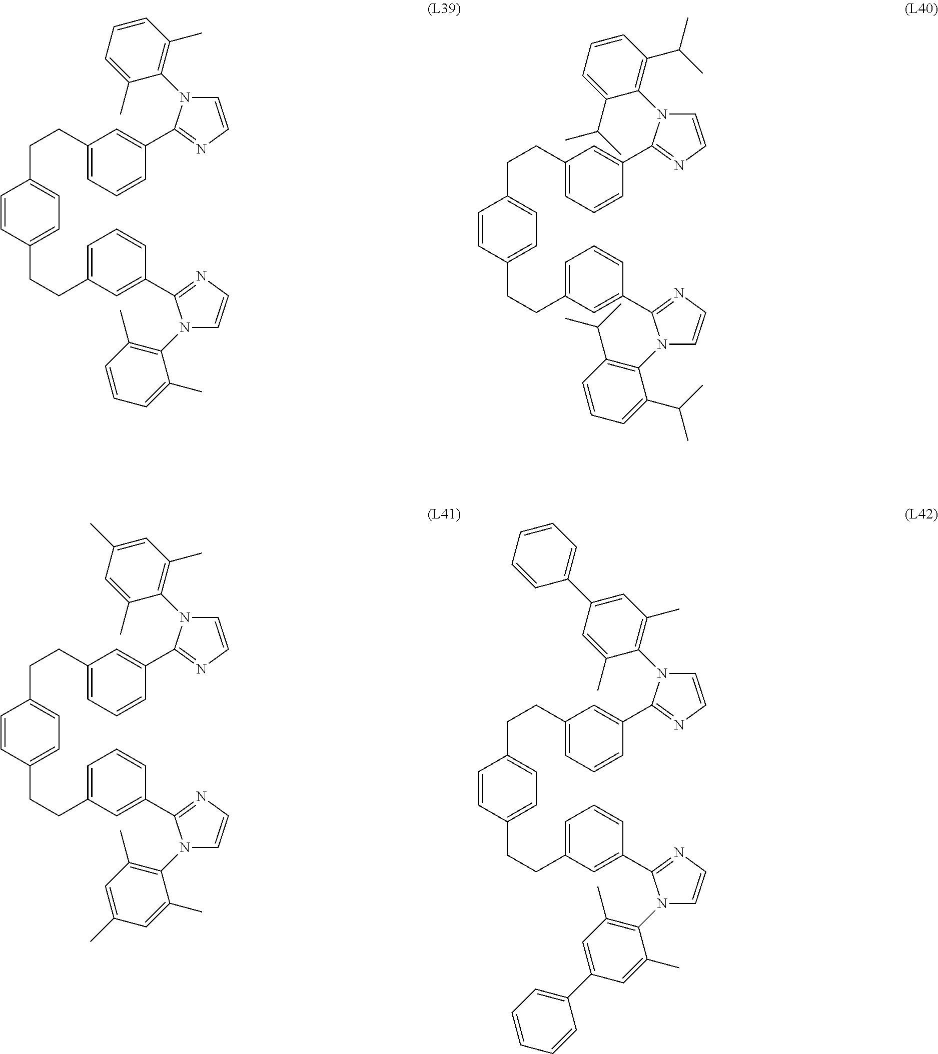 [SMILES: Cc1cccc(C)c1-n1ccnc1-c1cccc(CCc2ccc(CCc3cccc(-c4nccn4-c4c(C)cccc4C)c3)cc2)c1 ; CC(C)c1cccc(C(C)C)c1-n1ccnc1-c1cccc(CCc2ccc(CCc3cccc(-c4nccn4-c4c(C(C)C)cccc4C(C)C)c3)cc2)c1 ; Cc1cc(C)c(-n2ccnc2-c2cccc(CCc3ccc(CCc4cccc(-c5nccn5-c5c(C)cc(C)cc5C)c4)cc3)c2)c(C)c1 ; Cc1cc(-c2ccccc2)cc(C)c1-n1ccnc1-c1cccc(CCc2ccc(CCc3cccc(-c4nccn4-c4c(C)cc(-c5ccccc5)cc4C)c3)cc2)c1]

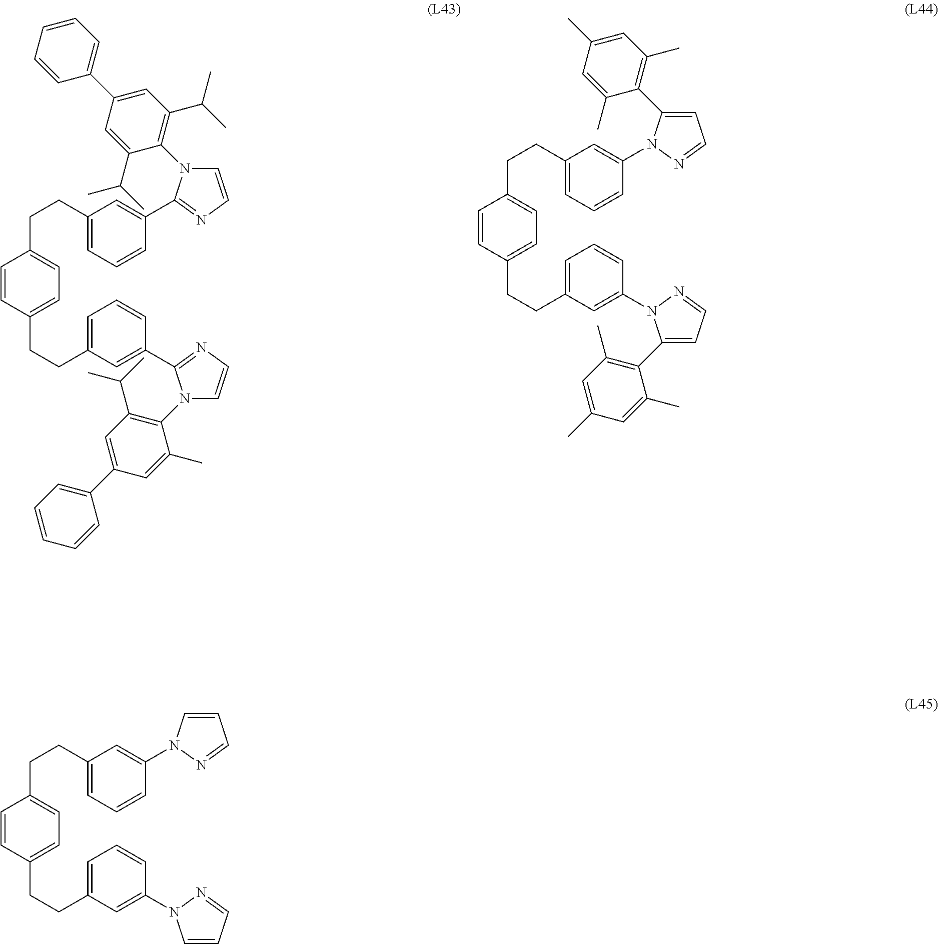 [SMILES: Cc1cc(-c2ccccc2)cc(C(C)C)c1-n1ccnc1-c1cccc(CCc2ccc(CCc3cccc(-c4nccn4-c4c(C(C)C)cc(-c5ccccc5)cc4C(C)C)c3)cc2)c1 ; Cc1cc(C)c(-c2ccnn2-c2cccc(CCc3ccc(CCc4cccc(-n5nccc5-c5c(C)cc(C)cc5C)c4)cc3)c2)c(C)c1 ; c1cc(CCc2ccc(CCc3cccc(-n4cccn4)c3)cc2)cc(-n2cccn2)c1]

The light emitting transition metal complexes in accordance with the present invention comprise other ligands in addition to the tetradentate ligands, which may be mono- or bidentate, preferably bidentate.

Preferred light emitting transition metal complexes in accordance with the present invention may be characterized by the general formulae 46

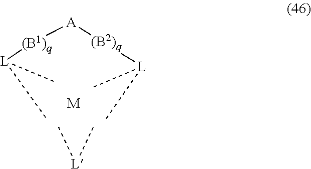

wherein L′ may be a bidentate ligand or a combination of two monodentate ligands, and is preferably a bidentate ligand of formula (3′)

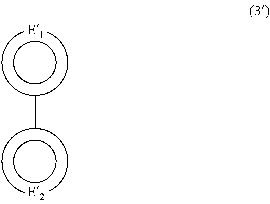

wherein

E′1 represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′2, and

E′2 represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′1, and

wherein the rings E′1 and E′2 could together form a polycyclic aliphatic, aromatic or heteroaromatic ring system and
wherein the ring E′1 is bound to the transition metal via a neutral donor atom which is a carbon in the form of a carbene or a heteroatom preferably a nitrogen atom and the ring E′2 is bound to the transition metal through a carbon atom having formally a negative charge or through a nitrogen atom having formally a negative charge.

Preferred additional bidentate ligands L′ in transition metal complexes of metals having a coordination number equal to six are ligands corresponding to the bidentate ligand units described hereinbefore for the tetradentate ligands. Such additional ligand may be identical to the ligand unit of the tetravalent ligand or it may be different therefrom thus yielding transition metal complexes with two identical bidentate ligand units forming a tetradentate ligand and a different bidentate ligand.

Bidentate ligand L′ may also be selected from ligands of general formulae E3-SBF, E3-Ar1-SBF, E3-Open SBF and/or E3-Ar1-Open SBF wherein E3 is a 5-membered heteroaryl ring, bound to the metal atom by covalent or dative bonds and containing at least one donor nitrogen atom, wherein said heteroaryl ring may be un-substituted or substituted by substituents selected from the group consisting of halogen, alkyl, alkoxy, amino, cyano, alkenyl, alkynyl, arylalkyl, aryl and heteroaryl group and/or may form an annealed ring system with other rings selected from cycloalkyl, aryl and heteroaryl rings;

Ar1 when present is bound to the metal atom by covalent or dative bonds and is selected from the group consisting of substituted or un-substituted C₆-C₃₀ arylene and substituted or un-substituted C₂-C₃₀ heteroarylene group, which Ar1 group may be un-substituted or substituted by substituents selected from the group consisting of halogen, alkyl, alkoxy, amino, cyano, alkenyl, alkynyl, arylalkyl, aryl and heteroaryl groups; SBF represents 9,9′-spirobifluorenyl, Open SBF represents 9,9-diphenyl-9H-fluorenyl, in both cases un-substituted or substituted by substituents selected from the group consisting of halogen, alkyl, alkoxy, amino, cyano, alkenyl, alkynyl, arylalkyl, aryl and heteroaryl groups.

The additional ligand L′ may also be a bidentate ligand like picolinate, tetrakispyrazolylborate or acetylacetonate (generally referred to as ancillary ligands) or monodentate ligands as have been described in the literature as suitable for the manufacture of transition metal complexes.

In another preferred embodiment, the additional bidentate ligand L′ is selected in order to impart to the resulting complexes a higher solubility in most organic solvents.

The metal M in the light emitting transition metal complexes in accordance with the present invention represents a transition metal of atomic number of at least 40 having a coordination number equal to six, preferably Ir, Ru, Os, Re or Rh, most preferably Ir.

The light emitting materials in accordance with the present invention generally have a number of advantageous properties. The increased bulkyness of the tetradentate ligands as compared to bidentate ligands often leads to a reduced T-T annihilation at high current densities as well as to a reduced aggregate-induced concentration quenching at high doping levels, which in turn leads to an increased device efficiency.

Because of their expected less labile ligand system, complexes involving tetradentate ligands in accordance with the present invention are believed to show improved chemical, thermal, electrochemical and photochemical stability as compared to their bidentate ligands analogs. Higher device lifetimes are thus expected.

Given their more rigid structure with decreased vibrational and rotational freedom, complexes comprising tetradentate ligands in accordance with the present invention are expected to show less efficient non-radiative decay pathways and thus increased photoluminescence quantum yields and higher devices efficiencies than their bidentate analogs.

The emission colour of the complexes involving symmetric tetradentate ligands in accordance with the present invention could be tuned over a large range of wavelengths according to the selected ligand unit L and the selected additional ligand L′. Without wishing to be bound to any theory, it is believed that if the triplet energy of the ligands unit L is lower than that of the additional ligand L′ or if the homoleptic complex [ML₃] based on the ligand unit L emits at a lower energy than the homoleptic complex [ML′₃] based on the additional ligand L′, the emission color of the heteroleptic complexes comprising the tetradentate ligand with ligand units L and the additional ligand L′ will be in a first approximation dictated by that of the ligand unit L and vice versa. So the “photoactive” ligand which is believed to contribute to the photoactive properties of the complexes comprising such ligands could be switched from the tetradentate ligand to the additional ligand L′ or vice versa according to the selected ligand unit L and additional ligand L′.

So ligand units L selected from the group consisting of compounds of formulae (11) to (26) are expected to lead to blue-emitting complexes provided L′ is suitably selected from ligands having a triplet energy at least equal to that of ligand unit L corresponding to compounds of formula (11) to (26). As mentioned before, especially blue-emitters need improvement in terms of lifetime and stability and the light-emitting materials in accordance with the present invention in preferred embodiments should provide significant advantages over the prior art in this regard as they should show a high efficiency while still providing a long lifetime.

More preferred blue emitting complexes in accordance with the present invention are those wherein the bidentate ligand units L of the symmetric tetradentate ligand as well as the additional bidentate ligand L′ pertain to general formula (11) and are thus represented by the following general formula (47):

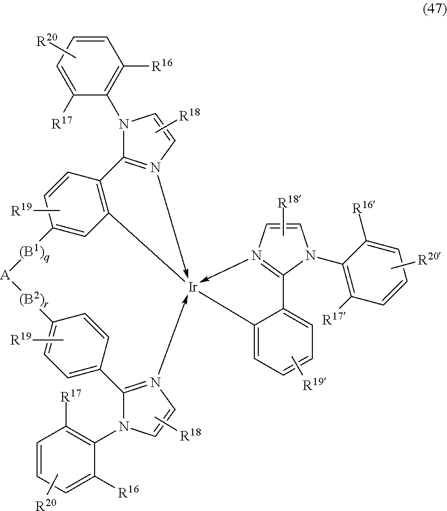

wherein A, B¹, B², q and r can have the same meanings as in general formula (1) and wherein R¹⁶ and R^{16′} can have the same meanings as defined for R¹⁶ in formula (11) and could be the same or different, R¹⁷ and R^{17′} can have the same meanings as defined for R¹⁷ in formula (11) and could be the same or different, R¹⁸ and R^{18′} can have the same meanings as defined for R¹⁸ in formula (11) and could be the same or different, R¹⁹ and R^{19′} can have the same meanings as defined for R¹⁹ in formula (11) and could be the same or different and R²⁰ and R^{20′} can have the same meanings as defined for R²⁰ in formula (11) and could be the same or different. For the sake of simplicity it has been chosen in formula (47) to bind the pending arms B¹ and B² to the phenyl ring of the bidentate ligand units L in para position to the imidazole ring; it is also possible, however, to bind the bidentate ligand units L to pending arms B¹ and B², if present, or to central scaffold A through any position or in any manner which does not interfere with those positions through which the bidentate ligand units L are bound to the transition metal.

Blue emitting complexes in a still preferred embodiment in accordance with the present invention are selected from those corresponding to formulae (48), (48)′, (49), (49′), (50) and (50′) wherein all the R groups have the same meaning as in formula (47). For the sake of simplicity, central scaffold A has been chosen to represent a benzene ring and B¹ and B² are CH₂—CH₂ units which are linked to A in meta positions to each other in formulae (48), (49) and (50) and in para positions to each other in formulae (48′), (49′) and (50′); it is also possible, however, to choose A, B¹ and B² from the broader definitions given hereinbefore as well as the way the pending arms B¹ and B², if present, are linked to the central scaffold A as indicated hereinbefore. Furthermore, for the sake of simplicity it has been chosen to bind the pending arms B¹ and B² to the phenyl ring of the bidentate ligand units L in para position to the imidazole ring in formulae (48), (49) and (50) and in meta position to the imidazole ring in formulae (48′), (49′) and (50′); it is also possible, however, to bind the bidentate ligand units L to pending arms B¹ and B², if present, or to central scaffold A through any position or in any manner which does not interfere with those positions through which the bidentate ligand units L of the symmetric tetradentate ligand are bound to the transition metal.

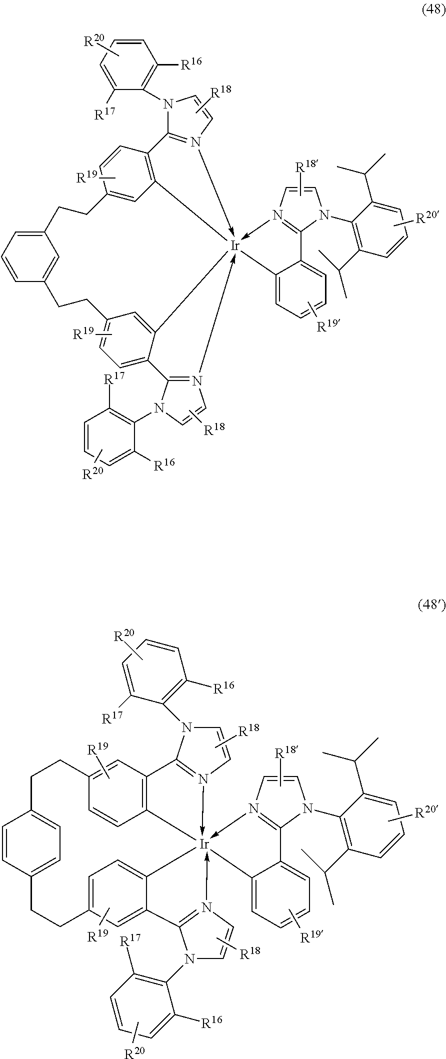

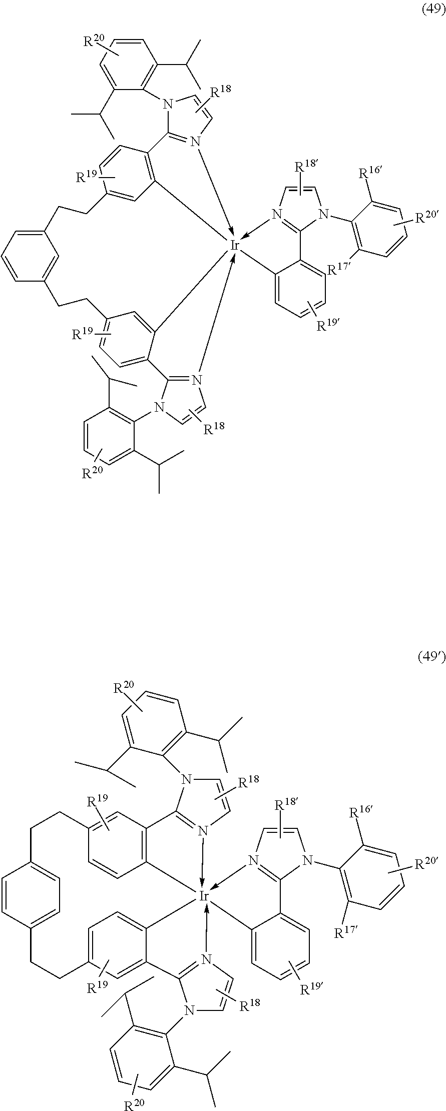

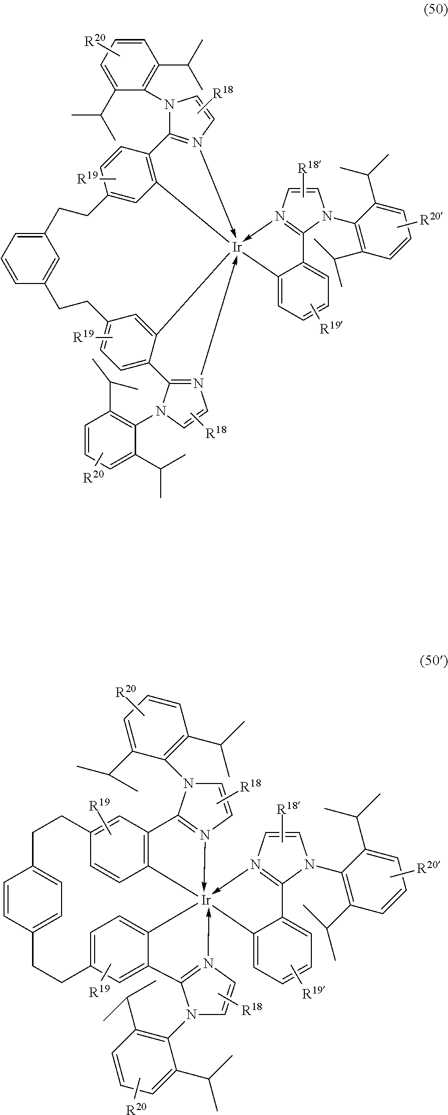

In the same way, provided L′ is suitably selected, green-emitting complexes are expected from tetradentate ligands involving ligand unit L based on formula (29) and orange/red emitting complexes from ligand units L corresponding to formulae (30) and (31).

Due to a fixed geometry of the coordinating ligands the precursor ligand, e.g. the dichloro Ir compound, will be synthesized primarily or solely as one isomer, e.g. the fac, leading to isomerically pure final complexes of the desired geometry.

Because of expected reduced ligand scrambling when starting from a tetradentate ligand wherein two ligands L are linked to one another, the syntheses of heteroleptic complexes (L≠L′) in accordance with the present invention are believed to lead to easier purification process and higher yield than synthesis starting from bidentate L and L′ ligands, which would be highly valuable. Heteroleptic complexes are indeed of particular interest because their photophysical, thermal and electronic properties as well as their solubility can be tuned by selecting appropriate combination of ligands. Furthermore, they have been observed in some cases (e.g. US2010/0141127A1) to yield better devices lifetimes in OLEDs.

Metal complexes in accordance with the present invention in preferred embodiments show a good solubility in organic solvents which is advantageous for low cost OLEDs production.

Another object of the invention is the use of the light emitting transition metal complexes as above described in the emitting layer of an organic light emitting device.

In particular, the present invention is directed to the use of the light emitting transition metal complexes as above described as dopant in a host layer, functioning as an emissive layer in an organic light emitting device.

Should the light emitting transition metal complexes be used as dopant in a host layer, they are generally used in an amount of at least 1% wt, preferably of at least 3% wt, more preferably of least 5% wt with respect to the total weight of the host and the dopant and generally of at most 35% wt, preferably at most 25% wt, more preferably at most 15% wt.

The present invention is also directed to an organic light emitting device, in particular an organic light emitting diode (OLED) comprising an emissive layer (EML), said emissive layer comprising the light emitting transition metal complexes or mixture of same as above described, optionally with a host material (wherein the light emitting transition metal complexes as above described are preferably present as a dopant), said host material being notably suitable in an EML in an OLED.

The present invention is also directed to light emitting electrochemical cells (LEEC) containing ionic complexes in accordance with the present invention.

An OLED generally comprises:

a substrate, for example (but not limited to) glass, plastic, metal;
an anode, generally transparent anode, such as an indium-tin oxide (ITO) anode;
a hole injection layer (HIL) for example (but not limited to) PEDOT/PSS;
a hole transporting layer (HTL);
an emissive layer (EML);
an electron transporting layer (ETL);
an electron injection layer (EIL) such as LiF, Cs₂CO₃
a cathode, generally a metallic cathode, such as an Al layer.

For a hole conducting emissive layer, one may have a hole blocking layer (HBL) that can also act as an exciton blocking layer between the emissive layer and the electron transporting layer. For an electron conducting emissive layer, one may have an electron blocking layer (EBL) that can also act as an exciton blocking layer between the emissive layer and the hole transporting layer. The emissive layer may be equal to the hole transporting layer (in which case the exciton blocking layer is near or at the anode) or to the electron transporting layer (in which case the exciton blocking layer is near or at the cathode).

The emissive layer may be formed with a host material in which the light emitting material or mixture of these materials as above described resides as a guest or the emissive layer may consist essentially of the light emitting material or mixture of these materials as above described itself. In the former case, the host material may e.g. be a hole-transporting material selected from the group of substituted tri-aryl amines. Preferably, the emissive layer is formed with a host material in which the light emitting material resides as a guest. The host material may be an electron-transporting material e.g. selected from the group of oxadiazoles, triazoles and ketones (e.g. Spirobifluoreneketones SBFK) or a hole transporting material. Examples of host materials are 4,4′-N,N′-dicarbazole-biphenyl [“CBP”] or 3,3′-N,N′-dicarbazole-biphenyl [“mCBP”] which have the formula:

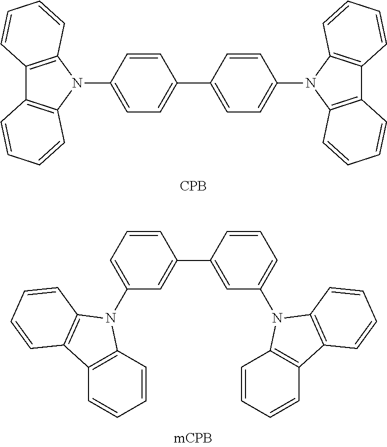 [SMILES: c1ccc2c(c1)c1ccccc1n2-c1ccc(-c2ccc(-n3c4ccccc4c4ccccc43)cc2)cc1 ; "CPB" ; c1cc(-c2cccc(-n3c4ccccc4c4ccccc43)c2)cc(-n2c3ccccc3c3ccccc32)c1]

Optionally, the emissive layer may also contain a polarization molecule, present as a dopant in said host material and having a dipole moment, that generally affects the wavelength of light emitted when said light emitting material as above described, used as dopant, luminesces.

A layer formed of an electron transporting material is advantageously used to transport electrons into the emissive layer comprising the light emitting transition metal complex and the (optional) host material. The electron transporting material may be an electron-transporting matrix selected from the group of metal quinoxolates (e.g. Alq₃, Liq), oxadiazoles, triazoles and ketones (e.g. Spirobifluorene ketones SBFK). Examples of electron transporting materials are tris-(8-hydroxyquinoline)aluminum of formula [“Alq₃”] and spirobifluoreneketone SBFK:

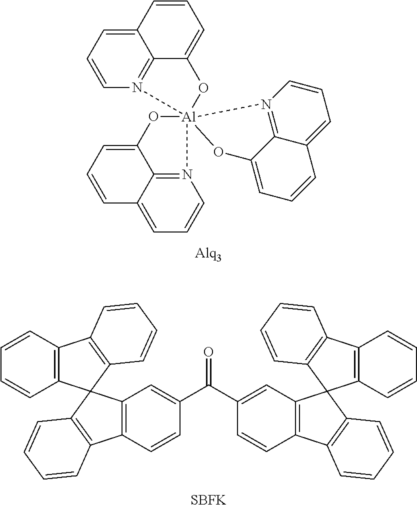

A layer formed of a hole transporting material is advantageously used to transport holes into the emissive layer comprising the light emitting material as above described and the (optional) host material. An example of a hole transporting material is 4,4′-bis[N-(1-naphthyl)-N-phenylamino]biphenyl [“α-NPD”].

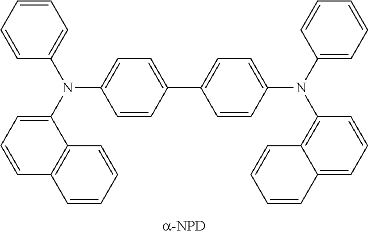 [SMILES: c1ccc(N(c2ccc(-c3ccc(N(c4ccccc4)c4cccc5ccccc45)cc3)cc2)c2cccc3ccccc23)cc1]

The use of an exciton blocking layer (“barrier layer”) to confine excitons within the luminescent layer (“luminescent zone”) is usually preferred. For a hole-transporting host, the blocking layer may be placed between the emissive layer and the electron transport layer. An example of a material for such a barrier layer is 2,9-dimethyl-4,7-diphenyl-1,10-phenanthroline (also called bathocuproine or “BCP”), which has the formula

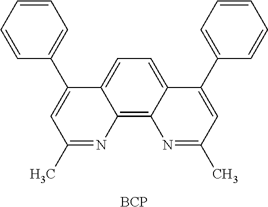 [SMILES: Cc1cc(-c2ccccc2)c2ccc3c(-c4ccccc4)cc(C)nc3c2n1 ; "BCP"]

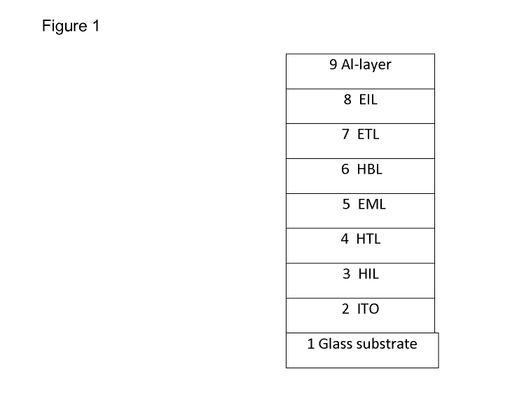

The OLED has preferably a multilayer structure, as depicted in FIG. 1, wherein 1 is a glass substrate, 2 is an ITO layer, 3 is a HIL layer comprising e.g. PEDOT/PSS, 4 is a HTL layer comprising e.g. α-NPD, 5 is an EML comprising e.g. mCBP as host material and the light emitting material or mixture of these materials as above defined as dopant in an amount of about 15% wt with respect to the total weight of host plus dopant; 6 is a HBL comprising e.g. BCP; 7 is an ETL comprising e.g. Alga; 8 is an EIL comprising e.g. LiF and 9 is an Al layer cathode

The symmetric tetradentate ligands forming part of the subunit of the light emitting transition metal complexes in accordance with the present invention may be obtained by a number of processes which have been principally described in the literature and are known to the skilled person.

By way of example a stepwise Sonogashira coupling reaction may be mentioned here.

The Sonogashira coupling reaction is a cross coupling reaction used widely in organic synthesis to form carbon-carbon bonds between a terminal alkyne group and an aryl or vinyl halide using a palladium based catalyst. The reaction has the advantage that it can be carried out under mild conditions, e.g. at room temperature and/or in aqueous media and with mild bases which is advantageous to avoid or suppress side reactions which may occur otherwise.

In principle the starting materials of the reaction may be a compound A-(B¹)-L¹ with a terminal ethynyl group which is reacted with a compound L² bearing a halide group or starting with a compound A-(B¹)-L¹ with a halide group which is reacted with a compound L² bearing a terminal ethynyl group. Respective starting materials may be obtained in accordance with methods known to the skilled person or are available commercially form certain suppliers.

Another possibility to obtain the symmetric tetradentate ligands present in the complexes of the present invention is the so called Suzuki-Myaura coupling, according to which phenylboronic acid reacts with haloarenes. The reaction proceeds smoothly in the presence of bases with good yields. The principle reaction scheme for coupling two phenyl units may be depicted as follows:

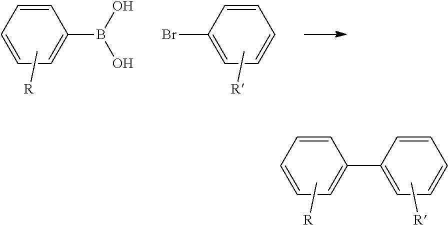

The reaction proceeds smoothly and under mild conditions with palladium compounds, e.g. tetrakis (triphenylphosphine)palladium, Pd(PPh3)4, as catalyst in the presence of bases like sodium hydroxide or sodium carbonate as bases. In some cases weak bases like sodium carbonate have proved to be advantageous over strong bases like NaOH.

Instead of the bromides, the respective iodides are also suitable reactants whereas the respective chlorides are usually inert under the reaction conditions.

Furthermore, the phenyl group in the above reaction scheme may be substituted or unsubstituted and the phenyl ring may be replaced by other aromatic or heteroaromatic ring systems to obtain a wide variety of compounds.

It is easily recognizable that subsequent repetition of this reaction can provide the desired symmetric tetradentate ligands.

Further details concerning the Suzuki-Myaura coupling and suitable reaction conditions can be taken from Suzuki et al., Synth. Comm. 11(7), 513-519 (1981).

Still another possibility to obtain the symmetric tetradentate ligands may be the arylation of primary or secondary amines with e.g. biphenyl compounds according to the following principal reaction scheme

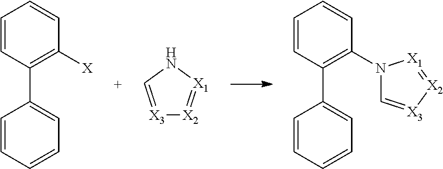

Similar to the Suzuki-Myura coupling the reaction can be repeatedly applied to obtain the desired compounds. Further details concerning reaction conditions can be taken from Angew. Chem. Int. Ed. 42, 2051-2053 (2003) to which reference is made in this regard. Similar to the Suzuki-Myaura coupling this reaction is a versatile tool and can be applied to a broad range of starting materials.

It is also possible to combine the two aforementioned reaction in two subsequent steps to obtain the desired tetradentate ligands.

The reaction conditions will be selected by the skilled person based on his professional knowledge and the information available for reactions of this type.

The light emitting transition metal complexes comprising symmetric tetradentate ligands in accordance with the present invention may be prepared using known methods described in the prior art literature.

A first preferred process to synthesize the light emitting transition metal complexes in accordance with the present invention which comprise a symmetric tetradentate ligand and an additional bidentate ligand L′ comprises reacting the halo-bridged dimer complex of general formula [L′₂M(μ-X)₂ML′₂] comprising the additional bidendate ligand L′ and bridging halide ligand X⁻ with the desired symmetric tetradentate ligand in a solvent mixture of an organic solvent and water comprising more than 25 vol % of water, based on the volume of the overall solvent mixture, at a temperature of from 50 to 260° C., optionally in the presence of from 0 to 5 molar equivalents, relative to the number of moles of halide X⁻ ion introduced into the reaction mixture through the halo-bridged dimer, of a scavenger for halide X⁻ ion and of from 0 to 10 vol %, based on the total volume of the solvent mixture, of a solubilisation agent increasing the solubility of the halo-bridged dimer in the reaction mixture.

The halo-bridged dimer complex of general formula [L′₂M(μ-X)₂ML′₂] which comprises the additional bidentate ligand L′ can be obtained according to known processes described in the literature, e.g. from metal halides and/or their hydrates reaction with additional bidentate ligand L′. Most preferred halides are chlorides and bromides. For example, in the case of iridium metal, a well-known procedure to synthesize the chloro-bridged dimer [L′₂Ir(μ-Cl)₂IrL′₂] consists to react IrCl₃.xH₂O with a slight excess of the bidentate ligand L′ (2.5 to 3 mol/mol Ir) in a 3:1 (v/v) mixture of 2-ethoxyethanol and water at reflux for ≈20 h.

In accordance with this preferred process, the reaction of the halo bridged dimer [L′₂M(μ-X)₂ML′₂] with the desired tetradentate ligand is carried out in a mixture of an organic solvent and water, which mixture comprises more than 25 vol % of water. The mixture preferably contains not more than 70 vol. % of an organic solvent and at least 30 vol. % of water.

According to this preferred process, the reaction is carried out in a solvent mixture comprising an organic solvent and water, preferably in a homogeneous solution. The term “homogeneous solution” used herein relates to the solvent mixture. Preferably, the organic solvent may be at least one selected from a group consisting of C₁˜C₂₀ alcohols, for example, methanol, ethanol, n-propanol, isopropanol, n-butanol, isobutanol or tert-butanol, oxanes, for example, dioxane or trioxane, C₁˜C₂₀ alkoxyalkyl ethers, for example, bis(2-methoxyethyl) ether, C₁˜C₂₀ dialkyl ethers, for example, dimethyl ether, C₁˜C₂₀ alkoxy alcohols, for example, methoxyethanol or ethoxyethanol, diols or polyalcohols, for example, ethylene glycol, propylene glycol, triethylene glycol or glycerol, polyethylene glycol, or dimethyl sulfoxide (DMSO), N-methyl pyrrolidone (NMP) or dimethyl formamide (DMF), and combinations thereof. More preferably, the organic solvent may be at least one selected from a group consisting of dioxane, trioxane, bis(2-methoxyethyl) ether, 2-ethoxyethanol and combinations thereof. Most preferably, the organic solvent is dioxane or bis(2-methoxyethyl) ether (hereinafter referred to as diglyme)

The reaction temperature is generally in the range of from 50 to 260° C., preferably in the range of from 80 to 150° C. In some specific embodiments, the process is carried out at a pressure of from 1×10³ to 1×10⁸ Pa, preferably 1×10⁴ to 1×10⁷ Pa, and most preferably 1×10⁵ to 1×10⁶ Pa.

The tetradentate symmetric ligand is preferably used in a stoichiometric amount relative to the amount of metal in the halo-bridged dimer or in a molar excess relative to the amount of metal in the halo-bridged dimer. In a more specific embodiment, the ligand compound is used in an amount of 10 to 3000 mol percent excess, preferably 50 to 1000 mol percent excess, most preferably 100 to 800 mol percent excess.

This process can be carried out in the presence or in the absence of a scavenger for halide ion X⁻. If halide ion scavenger is present, it is used in amount of up to 5, preferably up to 3 moles per mole of halide X⁻ ion introduced into the reaction mixture through the halo-bridged dimer. Preferred scavengers are silver salts. Most preferred silver salts are tetrafluoroborate, trifluoroacetate or triflate.

In certain cases, where the solubility of the halo-bridged dimer in the solvent mixture is very low, it has proven to be advantageous to add up to 10 vol %, preferably of from 0.1 to 10 vol %, even more preferably of from 0.5 to 5 vol %, based on the volume of the solvent mixture, of a solubilising agent to improve the solubility of the dimer in the reaction solvent. DMSO has shown to work particularly well as solubilizing agent in certain cases.

Given that proton ions, H₃O⁺, produced during the reaction may have an inhibitory effect, a neutralization step could be preferably carried out during the reaction in order to improve the complex yields.

In one embodiment of this process the halo-bridged dimer complex of general formula [L′₂M(μ-X)₂ML′₂] involving the additional bidendate ligand L′ could be treated in a 1st step with a scavenger for halide ion (most preferred scavenger being silver salt, silver triflate e.g.) in an organic solvent, e.g. a CH₂Cl₂/MeOH mixture or ethanol and the intermediate complex obtained after filtration and removal of solvents can be reacted in a 2^{nd} step with the desired symmetric tetradentate ligand at a temperature of from 50 to 260° C. in a solvent mixture of an organic solvent and water comprising more than 25 vol % of water.

In another embodiment of this process, the precursor complex obtained by reaction of the desired tetradentate symmetric ligand with metal halides and their hydrates, which could be considered as a halo-bridged dimer complex, was reacted with the desired additional bidendate ligand L′ in a solvent mixture of an organic solvent and water comprising more than 25 vol % of water, based on the volume of the overall solvent mixture, at a temperature of from 50 to 260° C., optionally in the presence of from 0 to 5 molar equivalents, relative to the number of moles of halide X⁻ ion introduced into the reaction mixture through the halo-bridged dimer, of a scavenger for halide X⁻ ion and of from 0 to 10 vol %, based on the total volume of the solvent mixture, of a solubilisation agent increasing the solubility of the halo-bridged dimer in the reaction mixture. For example, this precursor complex in the case of iridium metal could be obtained by reacting IrCl₃.xH₂O with a stoichiometric or a slight excess amount of the desired tetradentate ligand (1.0 to 3.0 mol/mol Ir) in a 3:1 (v/v) mixture of 2-ethoxyethanol and water at reflux for ≈20 h.

The precursor complex obtained by reaction of the desired tetradentate symmetric ligand with the selected metal halides could also be used as starting material in other synthesis routes to the light-emitting transition metal complexes in accordance with this invention.

Such precursor could e.g. be treated directly with the bidentate additional ligand L′ in an organic solvent at a temperature in the range of from 40° C. to 260° C.

Alternatively the same precursor could be treated in a first step with a scavenger for halide ion in a organic solvent, e.g. a methanol/dichloromethane mixture, ethanol or acetone, and the intermediate complex obtained after filtration and removal of the solvent is treated in a second step with the additional bidentate ligand L′ in an organic solvent at a temperature in the range of from 40° C. to 260° C.

A one-pot variant of this synthesis could also be used. In that case the precursor is made reacting with the additional bidentate ligand L′ in presence of a scavenger for halide ion in an organic solvent at a temperature in the range of from 40° C. to 260° C.

The reaction with the additional bidentate ligand L′ in these three last cases could be performed in presence of an organic or inorganic base in order to increase the yield.

Preferably, the organic solvent used to perform the reaction with the additional bidentate ligand L′ in these three last synthesis routes may be at least one selected from a group consisting of chlorinated solvents, for example CH₂Cl₂, C₁˜C₂₀ alcohols, for example, methanol, ethanol, n-propanol, isopropanol, n-butanol, isobutanol or tert-butanol, oxanes, for example, dioxane or trioxane, C₁˜C₂₀ alkoxyalkyl ethers, for example, bis(2-methoxyethyl) ether, C₁˜C₂₀ dialkyl ethers, for example, dimethyl ether, C₁˜C₂₀ alkoxy alcohols, for example, methoxyethanol or ethoxyethanol, diols or polyalcohols, for example, ethylene glycol, propylene glycol, triethylene glycol or glycerol, polyethylene glycol, C₁˜C₂₀ ketones, for example acetone, butanone, or dimethyl sulfoxide (DMSO), N-methyl pyrrolidone (NMP), acetonitrile or dimethyl formamide (DMF), and combinations thereof.

A three-step synthesis analogous to that described in JP2008/303150 for the synthesis of homoleptic complexes involving 2-phenylimidazole type ligands which starts from IrCl₃ and passes successively by the chloro-bridged dimer and the heteroleptic acac complex to finally obtain the tris homoleptic complexes could also be used. In this case, the dimer precursor obtained from the reaction of the desired tetradentate symmetric ligand with the selected metal halides (MX₃.xH₂O) could be reacted with acetylacetonate type ligands in presence of a base (e.g. Na₂CO₃) in an organic solvent, e.g. 2-ethoxyethanol, to lead to a heteroleptic complex comprising the symmetric tetradentate ligand as the main ligand and acetylacetonate as ancillary bidentate ligand. In a last step the heteroleptic complex comprising the acetylacetonate as ancillary can then be reacted with an additional bidentate ligand L′ to give the desired heteroleptic complex which thus comprises the desired symmetric tetradentate ligand and the desired additional bidentate ligand L′.

Metal acetylacetonate complexes (e.g. (Ir(acac)₃) could also be used as starting materials. It has been shown that light emitting transition metal complexes comprising symmetric tetradentate ligands in accordance with the present invention could be obtained e.g. by treating Ir(acac)₃) with a mixture of the desired tetradentate symmetric ligand and of the selected additional bidentate ligand L′ at high temperature (>200° C.) without any added solvent.

When the additional bidentate L′ ligand corresponds to a ĈC ligand which is bound to the metal via a neutral donor atom which is a carbon in the form of a carbene and through a carbon atom having formally a negative charge, a carbene precursor complex involving the additional bidentate ligand L′ could be first prepared which is then allowed to react in a second step with the desired tetradentate ligand in presence of a silver salt. In the case of iridium e.g., this carbene precursor could be an iridium (I) complex e.g. [Ir(COD)(L′)Cl] wherein COD corresponds to a 1,5-cyclooctadiene ligand and wherein L′ is linked to the iridium (I) ion via its carbene part.

The light-emitting transition metal complexes in accordance with our invention may be purified by recrystallization, column chromatography or sublimation to name only a few possibilities

The skilled person will use his professional knowledge to select the suitable reactants and reaction conditions based on the specific combination of tetradentate and bidentate or monodentate ligands.

Other synthesis methods are suitable and are known to the skilled person so that no further details are necessary here.

The light emitting transition metal complexes in accordance with the present invention provide the possibility to precisely adjust and modify the properties by selection of the ligand units L in accordance with the specific application case.

Thereby the emission properties of organic electronic devices comprising the light emitting materials in accordance with the present invention can be finely tuned and adjusted to the specific application.

The following examples further explain the invention without limiting same.)

### 1°) Synthesis of KIM Complexes Wherein the Bidentate Ligand Units L of the Symmetric Tetradentate Ligand Pertain to General Formula (8) and More Particularly to General Formula (11)

### EXAMPLE 1

Synthesis of complex I (formula hereafter) wherein the bidentate ligand units L of the symmetric tetradentate ligand as well as the additional bidentate ligand L′ pertain to general formula (11). More specifically, the symmetric tetradentate ligand corresponds to ligand of formula (L32) wherein the bidentate ligand units L pertain to formula (16) while the additional bidentate ligand L′ pertains to formula (17).

In this case, the bidentate ligand units L of the symmetric tetradentate ligand as well as the additional bidentate ligand L′ correspond to cyclometallated CAN ligands which means that they are bound to the iridium metal via a neutral donor nitrogen atom and through a carbon atom having formally a negative charge.

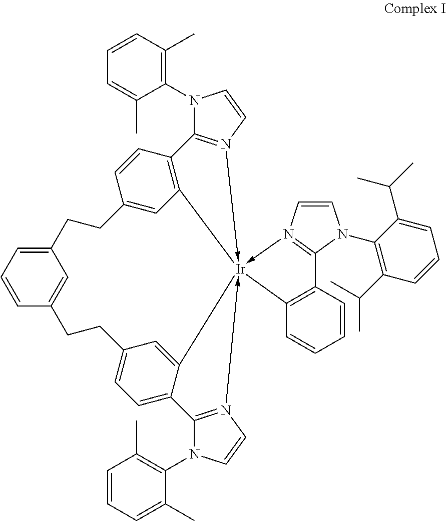

### a) Synthesis of Symmetric Tetradentate Ligand of Formula (L32)

The bidentate ligand units L of the symmetric tetradentate ligand (L32) pertain to general formula (11) and more specifically to formula (16); the central scaffold A is a phenyl ring and both pending arms B¹ and B² are —CH₂—CH₂— units linked in meta position to each other on the A phenyl ring.

The ligand L32 was synthesized according to the following scheme:

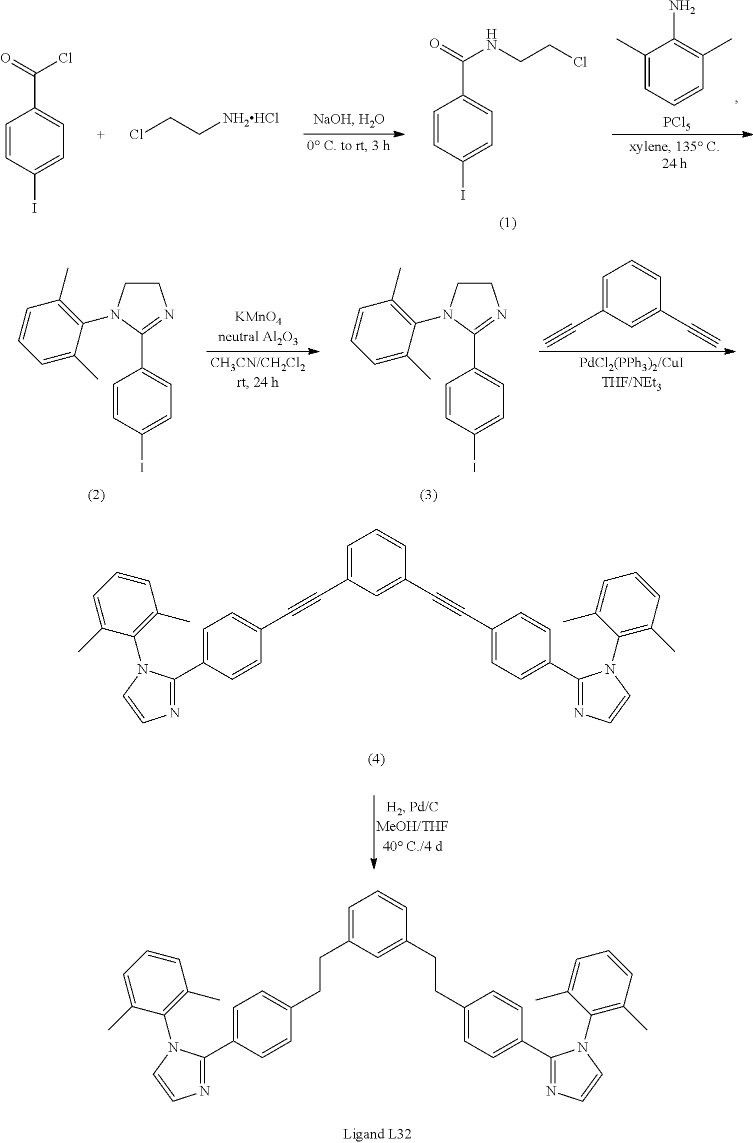

### Step 1: Synthesis of N-(2-chloroethyl)-4-iodobenzamide (1)

100 mL of aq. NaOH 2M were introduced in a 250 mL three-neck round bottom flask and cooled in an ice bath. Then 10.6 g of 2-chloroethylamine hydrochloride (91 mmol) were added. The resulting suspension was stirred until the salt was completely dissolved. A solution of 4-iodobenzoyl chloride (26.6 g, 100 mmol) in dioxane (80 mL) was then added dropwise via an addition funnel into the vigorously stirred solution at 0-4° C. After addition, the solution was stirred successively for 1 h at 0-4° C. and for 1 h at room temperature. The resulting solid was filtered and the recovered wet product was dissolved in CH₂Cl₂. After drying over MgSO₄ and filtration, the solution was concentrated in vacuo to afford the desired product as a white solid as confirmed by ¹H-NMR and LC-MS analysis.

Yield: 90%.

¹H NMR (400 MHz, DMSO-d₆) δ 8.80 (dd, J=8.8, 3.1 Hz, 1H), 7.93-7.80 (m, 2H), 7.72-7.57 (m, 2H), 3.72 (t, J=6.3 Hz, 2H), 3.56 (dd, J=12.0, 6.1 Hz, 2H).

### Step 2: Synthesis of 1-(2,6-dimethylphenyl)-2-(4-iodophenyl)-4,5-dihydro-1H-imidazole (2)

To a dried 250 mL round-bottom flask were added 15.5 g (50 mmol) of N-(2-chloroethyl)-4-iodobenzamide from step 1 followed by 150 mL of anhydrous o-xylene under argon. Phosphorous pentachloride (16.7 g, 80 mmol) was then added and the reaction mixture was heated to reflux under argon until PCl₆ was completely dissolved (≈2 h). The solution was then cooled to room temperature whereupon 6.7 g of 2,6-dimethylaniline (55 mmol) were added dropwise (a base trap was attached to the condenser to neutralize generated HCl gas). After addition, the mixture was heated to 120° C. for 20 hrs and then to 150° C. for 4 hrs. After cooling down to room temperature the imidazoline was collected on a filter and washed with toluene and petroleum ether. The resulting solid was dissolved in CH₂Cl₂ and washed with NH₄OH 10%. The organic layer was dried over MgSO₄, filtered and evaporated to obtain 20.9 g of 1-(2,6-dimethylphenyl)-2-(4-iodophenyl)-4,5-dihydro-1H-imidazole as off-white solid.

¹H NMR (400 MHz, DMSO-d₆) δ 7.60 (d, J=8.4 Hz, 2H), 7.09 (d, J=8.3 Hz, 2H), 7.07-7.00 (m, 3H), 3.98 (t, J=10.3 Hz, 2H), 3.69 (t, J=10.2 Hz, 2H), 2.15 (s, 6H).

### Step 3: Synthesis of 1-(2,6-dimethylphenyl)-2-(4-iodophenyl)-1H-imidazole (3)

To a 500 mL round-bottom flask were added 7.52 g of 1-(2,6-dimethylphenyl)-2-(4-iodophenyl)-4,5-dihydro-1H-imidazole from step 2 (20 mmol) and 220 mL of acetonitrile. This mixture was stirred at room temperature until complete dissolution. A mixture of 3.38 g KMnO₄ (21.4 mmol) and 7.92 g of neutral alumina (ground together to a fine homogeneous power) was then added in small portions to the stirred solution and the resulting suspension was stirred at room temperature for 16 h. Two other additions of KMnO₄ (1.36 g) and neutral alumina (3.22 g) each followed by heating at room temperature for 16 h were needed to complete the reaction as shown by LC-MS analysis. The reaction mixture was then quenched with 100 mL of ethanol and stirred for 30 min to reduce the excess oxidant. Afterwards it was filtered on celite (diatomaceous earth), the filtrate was evaporated and the residue was purified on silica gel column using petroleum ether/CH₂Cl₂ mixtures (50/50→0/100), followed by CH₂Cl₂/ethyl acetate mixtures (20/1). The product fractions were evaporated of solvent to afford the desired product as white solid as confirmed by ¹H NMR (3.88 g, yield: 51.8%).

¹H NMR (400 MHz, CDCl₃) δ 7.54 (d, J=8.5 Hz, 2H), 7.36-7.27 (m, 2H), 7.14 (dd, J=15.3, 8.1 Hz, 4H), 6.92 (s, 1H), 1.95 (s, 6H).

m/z (ESI-MS+) ([M+H]⁺) found 375.0351

### Step 4: Synthesis of 1,3-bis((4-(1-(2,6-dimethylphenyl)-1H-imidazol-2-yl)phenyl)ethynyl)benzene (4)

3.21 g of 1-(2,6-dimethylphenyl)-2-(4-iodophenyl)-1H-imidazole (8.6 mmol) from step 3 and 0.57 mL (4.3 mmol) of 1,3-diethynylbenzene were dissolved in 60 mL of a 1:1 mixture of THF and triethylamine. Nitrogen was bubbled through the solution for 10 min. 0.18 g (0.26 mmol) of PdCl₂(PPh3)₂ were added, followed by the addition of 0.16 g (0.86 mmol) of CuI. The reaction mixture was heated at 65° C. under nitrogen over night. After letting the mixture cool down to room temperature, it was extracted between CH₂Cl₂ and water. The organic layer was dried over MgSO₄, filtered and the solvent removed. The crude product was purified by column chromatography (SiO₂; CHCl₃/EtOAc 1:1) to get the product as an off-white solid. Yield: 2.4 g (90%).

m/z (ESI-MS+) ([M+H]⁺) found 619.2861.

### Step 5: Synthesis of 1,3-bis(4-(1-(2,6-dimethylphenyl)-1H-imidazol-2-yl)phenethyl)benzene ligand L32

30 g of 1,3-bis((4-(1-(2,6-dimethylphenyl)-1H-imidazol-2-yl)phenyl)ethynyl)benzene obtained as in step 4 were dissolved in a THF/MeOH mixture (50 mL/250 mL). 14.5 g of acetic acid were added and the resulting mixture was stirred for 2 h. 60 g of palladium on activated charcoal (10 wt %) were then added and the mixture was stirred under hydrogen (1 MPa) at 35° C., the reaction being monitored by LC-MS. The system was exchanged with H₂ for several times to complete the reaction (an extra charge of catalyst could also be used to complete the reaction). After 80 h, the reaction mixture was filtered and concentrated. The residue was dissolved in CH₂Cl₂, washed using saturated NaHCO₃ and brine, dried over MgSO₄, filtered and concentrated leading to 23 g of a yellow oily solid. The crude solid was further purified by silica gel column chromatography using successively petroleum ether/ethyl acetate 4:1 and CH₂Cl₂/ethyl acetate 1:1.5 mixtures followed by recrystallization of the so recovered fractions in ethyl acetate, leading to 18 g of the desired L32 ligand as confirmed by NMR and LC-MS analysis.

¹H NMR (300 MHz, CDCl₃) δ 7.31-7.12 (m, 9H), 7.12-7.00 (m, 5H), 6.90 (t, J=8.9 Hz, 4H), 6.88-6.78 (m, 4H), 2.71 (s, 8H), 1.87 (s, 12H).

m/z (ESI-MS+) calcd. 627.3482 ([M+H]⁺) found 627.3477.

### b) Complex I Synthesis

1st step: preparation of chloro-bridged dimer [(L′₁)₂Ir(μ-Cl)₂Ir(L′₁)₂] from IrCl₃xH₂O and 1-(2,6-diisopropylphenyl)-2-phenyl-1H-imidazole additional ligand L′₁.

In a 500 mL round bottom flask flushed with argon were introduced IrCl₃.xH2O (6.48 g, 18.3 mmol) and 1-(2,6-diisopropylphenyl)-2-phenyl-1H-imidazole ligand (16.74 g, 55 mmol) followed by addition of 356 mL of a 3:1 (v/v) mixture of 2-ethoxy-ethanol and water. The resulting mixture was outgassed and heated under stirring at reflux for 21 h. After cooling, the precipitate was filtered off with suction, washed with methanol and dried under vacuum. The reaction yield was 84%.

2^{nd} step: reaction of tetradentate ligand L32 with dimer [(L′₁)₂Ir(μ-Cl)₂Ir(L′₁)₂]

To 0.311 g of the dimer from 1st step were successively added 10 mL of CH₂Cl₂ and 0.098 g of silver triflate dissolved in 10 mL of methanol. After being stirred for 2 hours at room temperature, the reaction mixture was filtered and evaporated to dryness. 36 mL of a solvent mixture of diglyme and water of 1:1 volume ratio was poured onto the residue. The resulting solution was transferred into a 50 mL vial flushed with argon and 0.293 g of the tetradentate ligand L32 were added under argon. After being sealed, the vial was heated under stirring at 130° C. for 144 h. After cooling, the precipitate was filtered off with suction and washed with water and hexane.

Complex I yield estimated from ¹H-NMR analysis of the “crude” product using octamethylcyclotetrasiloxane as internal standard was equal to 17.5%. The “crude” recovered solid could be purified by two subsequent silica gel column chromatography using ethylacetate/hexane 7:3 (v/v) mixture as eluent in the 1st and dioxane/hexane 3:7 (v/v) mixture in the 2^{nd}. This led to a mixture of complex I (75%) and of tris homoleptic complex [Ir(L′₁)₃] (25%) as confirmed by ¹H-NMR and LC-MS analysis.

λₘₐₓ emission in 2-MetTHF solutions (10⁻⁵ M) at room temperature: 471 (max), 504 nm

### EXAMPLE 2

Synthesis of complex II (formula hereafter) wherein the bidentate ligand units L of the symmetric tetradentate ligand pertain to general formula (11) while the additional bidentate ligand L′ pertains to general formula (12). More specifically, the additional bidentate ligand L′ pertains to formula (23) while the symmetric tetradentate ligand corresponds to ligand of formula (L32) wherein the bidentate ligand units L pertain to formula (16).

In this case also, the bidentate ligand units L of the symmetric tetradentate ligand as well as the additional bidentate ligand L′ correspond to cyclometallated CAN ligands which means that they are bound to the iridium metal via a neutral donor nitrogen atom and through a carbon atom having formally a negative charge.

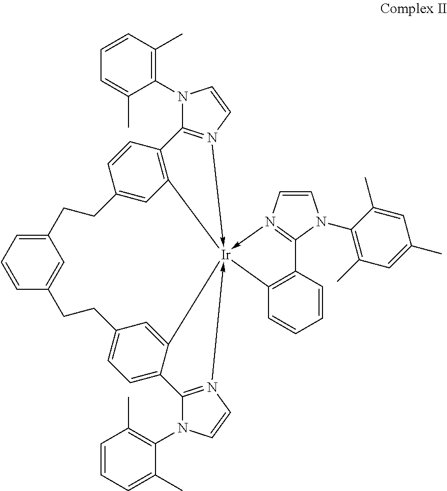

Complex II Synthesis

220 mL of 2-ethoxyethanol were placed in a 2-neck flask and nitrogen was bubbled through the solution. 0.85 g (1.36 mmol) of the tetradentate ligand L32 was dissolved in 10 mL of hot 2-ethoxyethanol and added to the vigorously stirred solution. After additional 10 min of nitrogen bubbling, 0.47 g (1.36 mmol) of IrCl₃.xH2O was added and the resulting mixture was heated to 120° C. over night. After cooling to room temperature, the mixture was poured into an excess of ice-cold water. The formed precipitate was filtered on a glass-frit and air-dried to get 0.74 g of a yellow powder. It was used for the next step without further purification.

0.3 g (0.176 mmol) of this precursor was suspended in 250 mL of ethylene glycol and the suspension was degassed by bubbling nitrogen. 0.23 g (1.06 mmol) of silver trifluoroacetate was added, followed by the addition of 0.18 g (0.7 mmol) of 5-mesityl-1-phenyl-1H-pyrazole additional ligand L′₂. The reaction mixture was protected from light and warmed to 70° C. for 1 hour. It was then heated to 190° C. over night. After cooling to room temperature the reaction mixture was extracted between CH₂Cl₂ and water. The organic phases were combined, dried over MgSO₄, filtered and the solvent removed. The crude product was purified by two subsequent columns on silica gel, employing hexane/ethyl acetate 8:2 as the solvent mixture. After removal of the solvent the desired product was obtained as a clear oil (23 mg).

MS-ESI: m/z: calcd. 1079.43518 [M+H⁺], found 1079.43606

λₘₐₓ emission (nm) in 2-MetTHF solutions: 467, 497 (max) at room temperature and 457 (max), 490 at 77K.

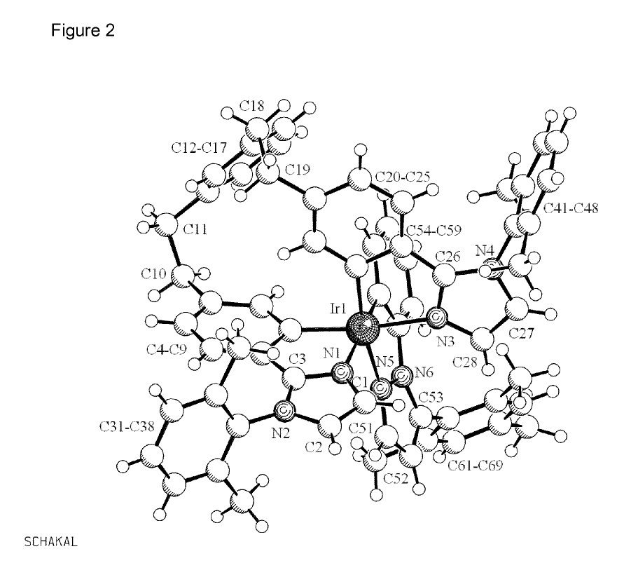

The crystal structure of complex II is given in FIG. 2. It corresponds to a facial isomer, the three coordinating nitrogen atoms (two from the tetradentate ligand L32 and one from the additional bidentate ligand L′₂) occupying one face of the octahedron.

### EXAMPLE 3

Synthesis of complex III (formula hereafter) wherein the bidentate ligand units L of the symmetric tetradentate ligand pertain to general formula (11) while the additional bidentate ligand L′ corresponds to a cyclometallated ĈC ligand which means that it is bound to the iridium metal via a neutral donor atom which is a carbon in the form of a carbene and through a carbon atom having formally a negative charge. More specifically, the symmetric tetradentate ligand corresponds to ligand of formula (L32) wherein the bidentate ligand units L pertain to formula (16). In this case, the bidentate ligand units L of the symmetric tetradentate ligand correspond to cyclometallated ĈN ligands while the additional bidentate ligand L′ corresponds to a cyclometallated ĈC ligand.

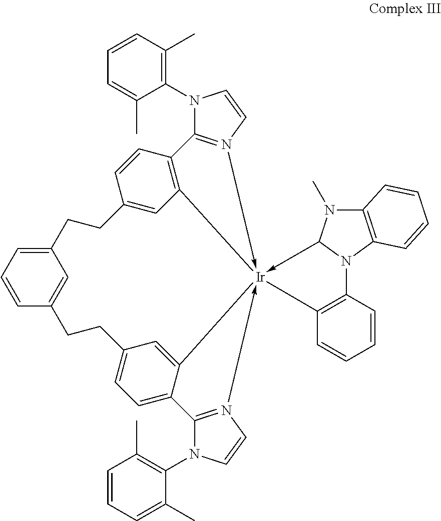

### a) Synthesis of the additional bidentate ĈC ligand L′₃

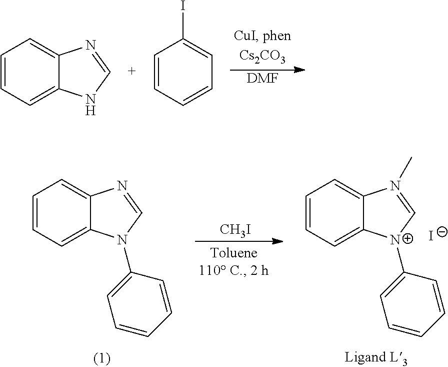

### Synthesis of 1-phenyl-1H-benzo[d]imidazole (1)

In an oven-dried two neck 250 mL round-bottom flask, CuI (646 mg; 3.4 mmol; 0.1 eq.), 1H-benzo[d]imidazole (4 g; 33.9 mmol; 1 eq.) and CsCO₃ (22.1 g; 67.8 mmol; 2 eq.) in anhydrous DMF (65 mL) were introduced. The reaction mixture was deoxygenated for 20 min by N2 bubbling. Then, iodobenzene (8.3 g; 4.5 mL; 40.6 mmol; 1.2 eq.) and 1,10-phenanthroline (1.2 g; 6.8 mmol; 0.2 eq) were successively added. The resulting mixture was heated at 110° C. for 24 hours in the dark under inert atmosphere. After that reaction time, additional iodobenzene (3.6 g; 2 mL; 18 mmol; 0.5 eq.) was added, and the reaction was heated at 110° C. for one extra day. After the reaction time, the reaction mixture was cooled to room temperature and filtered. The filtered solids were washed with 120 mL of ethyl acetate. The filtrate was concentrated under vacuum. In order to remove the DMF, water (100 mL) was added to the residue and the aqueous phase was subsequently extracted with more ethyl acetate (3×30 mL). The combined organic layers were dried over MgSO₄ and the solvent removed using a rotavap. The residue was purified on column chromatography employing mixtures of hexane:ethyl acetate (2:1-0:1). The product was obtained as a yellow liquid. Yield: 4.8 g; 27.7 mmol; 73%.

¹H NMR (400 MHz, DMSO-d₆) δ 8.56 (s, 1H), 7.78 (dd, J=6.5, 2.4 Hz, 1H), 7.73-7.59 (m, 5H), 7.51 (dd, J=10.2, 4.3 Hz, 1H), 7.38-7.26 (m, 2H)

### Synthesis of 3-methyl-1-phenyl-1H-benzo[d]imidazol-3-ium ligand L′₃

In a 50 mL round-bottom flask, 1-phenyl-1H-benzo[d]imidazole (4.8 g; 25 mmol; 1 eq.) and CH₃I (8.8 g; 3.9 mL; 62 mmol; 2.5 eq.) were introduced in toluene (2 mL). The mixture was heated at 110° C. for 6 hours. After that time, a white precipitate appeared. The precipitate was then washed with THF (20 mL) and toluene (20 mL). The product was obtained as a white microcrystalline powder. Yield: 8.1 g; 24 mmol; 96%.

¹H NMR (400 MHz, CDCl₃) δ 11.05 (s, 1H), 7.85 (dd, J=18.2, 8.6 Hz, 3H), 7.76-7.55 (m, 6H), 4.47 (s, 3H).

### b) Preparation of (cyclooctadiene)(1-methyl-3-phenyl-2,3-dihydro-1H-benzo[d]imidazol-2-yl)iridium(I) chloride [Ir(NHC)(COD)Cl]iridium carbene precursor complex

The synthesis was carried out according to a slightly modified procedure from the one reported on Dalton Trans. 2013, 42, 7318-7329.

Dry THF (120 mL) was added to a 2-neck round-bottom flask containing 3-methyl-1-phenyl-1H-benzo[d]imidazol-3-ium ligand L′₃ (1.0 g; 3.0 mmol; 2 eq.), [Ir(COD)Cl]₂ (1.0 g; 1.5 mmol; 1 eq.) and NaN(SiMe₃)₂(0.6 g; 3.0 mmol; 2 eq.) under nitrogen atmosphere. A color change from yellow to dark brown was observed. The reaction mixture was degassed by nitrogen bubbling for 20 minutes and allowed to stir for 3 h protected from light with aluminum foil. After this time, the solvent was removed in vacuo and the residue purified by column chromatography on silica employing mixtures of cyclohexane:DCM (2:1-1:1 v/v). The product was obtained as a bright yellow/green microcrystalline solid. Yield: 1.5 g; 2.76 mmol; 93%.

¹H NMR (400 MHz, CD₂Cl₂) δ 8.00 (d, J=7.1 Hz, 2H), 7.54 (dd, J=11.6, 7.3 Hz, 3H), 7.41 (d, J=7.9 Hz, 1H), 7.31 (dd, J=12.2, 7.8 Hz, 2H), 7.24 (d, J=8.1 Hz, 1H), 4.80 (m, 1H), 4.69 (m, 1H), 4.16 (s, 3H), 3.11 (m, 1H), 2.49 (m, 1H), 2.12 (m, 2H), 1.75 (m, 1H), 1.64 (m, 2H), 1.34 (m, 1H), 1.21 (m, 1H), 1.07 (m, 1H).

### c) Synthesis of Complex III

0.300 g of ligand L32 (0.482 mmol; 1.1 eq.) was dissolved in 2-ethoxyethanol (300 mL) and the solution was degassed by nitrogen bubbling for 30 minutes. After this time, the iridium carbene precursor complex (238 mg; 0.438 mmol; 1 eq.) and AgOAc (110 mg; 0.657 mmol; 1.5 eq.) were added and the flask subjected to three rapid nitrogen-vacuum-nitrogen cycles. The flask was heated to 140° C. under nitrogen in darkness for 3 days. After this time, the solvent was removed in vacuo and the residue purified rapidly by column chromatography in darkness (protected with aluminium foil) on silica, eluting with mixtures of cyclohexane:EtOAc (20:1-10:1-5:1 v/v). The product appears to decompose slightly on silica and is obtained as a mixture of isomers.

Yield: ˜50 mg.

m/z (MALDI-MS) calcd. 1025.388 ([M+H]⁺) found 1025.371.

λₘₐₓ emission (nm) in toluene solution at room temperature: 455, 486ₘₐₓ, 520ₛₕ, 564ₛₕ.)

### 2°) Synthesis of Ir(III) Complexes Wherein the Bidentate Ligand Units L of the Symmetric Tetradentate Ligand Pertain to General Formula (8) and More Particularly to General Formula (12)

### EXAMPLE 4

Synthesis of complex IV (formula hereafter) wherein the

bidentate ligand units L of the symmetric tetradentate ligand pertain to general formula (12) while the additional bidentate ligand L′ pertains to general formula (11). More specifically, the additional bidentate ligand L′ pertains to formula (17) while the symmetric tetradentate ligand corresponds to ligand of formula (L37) wherein the bidentate ligand units L pertain to formula (23).

In this case as in examples 1 and 2, the bidentate ligand units L of the symmetric tetradentate ligand as well as the additional bidentate ligand L′ correspond to cyclometallated CAN ligands which means that they are bound to the iridium metal via a neutral donor nitrogen atom and through a carbon atom having formally a negative charge.

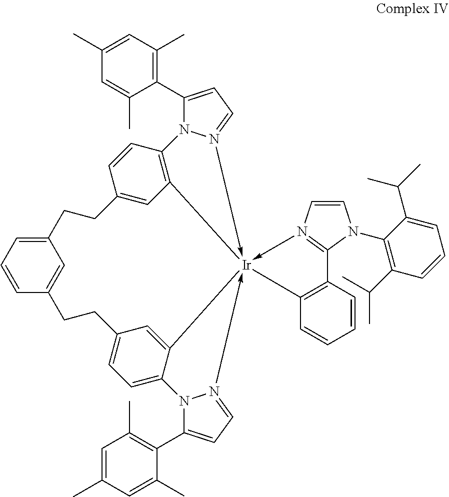

### a) Synthesis of Symmetric Tetradentate Ligand of Formula (L37)

The bidentate ligand units L of symmetric tetradentate ligand of formula (L37) pertain to general formula (12) and more specifically to formula (23); the central scaffold A is a phenyl ring and both pending arms units B¹ and B² are —CH₂—CH₂— units linked in meta position to each other on the A phenyl ring.

The ligand L37 was synthesized according to the following scheme:

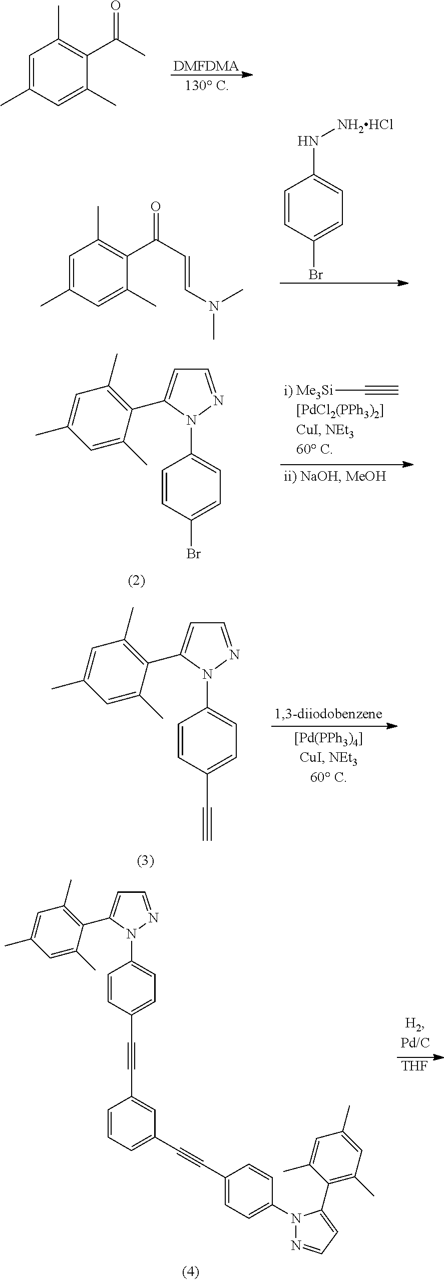

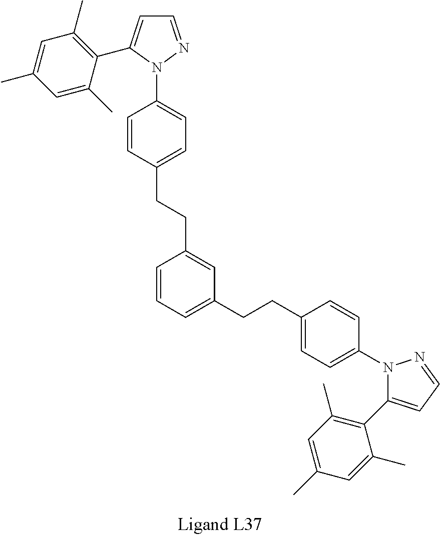 [SMILES: Cc1cc(C)c(-c2ccnn2-c2ccc(CCc3cccc(CCc4ccc(-n5nccc5-c5c(C)cc(C)cc5C)cc4)c3)cc2)c(C)c1]

### Step 1: Synthesis of (E)-3-(dimethylamino)-1-mesitylprop-2-en-1-one (1)

33.2 mL of N,N-dimethylformamide dimethyl acetal (0.250 mol) were added under nitrogen in one portion to a solution of 2′,4′,6′-trimethylacetophenone (32.9 mL; 0.198 mol) in dry DMF (590 mL) outgassed beforehand with nitrogen. The reaction mixture was heated at 130° C. for 2 days, monitored by TLC. After cooling down to room temperature, the solvent was removed and the oily residue was purified by flash silica gel column chromatography using ethyl acetate/hexane 7:3 mixture. Yield: 36.8 g, 85%).

¹H NMR (400 MHz, DMSO) δ 6.81 (s, 2H), 5.10 (d, J=12.5 Hz, 2H), 2.87 (d, J=70.4 Hz, 6H), 2.22 (s, 3H), 2.09 (s, 6H).

m/z (ESI-MS+) calcd 218.1539 ([M+H]⁺) found 218.1543

### Step 2: Synthesis of 1-(4-bromophenyl)-5-mesityl-1H-pyrazole (2)

45.3 g of 4-bromophenylhyhydrazine hydrochloride (0.20 mol) were added to a solution of 3-(dimethylamino)-1-mesitylprop-2-en-1-one (40 g, 0.18 mol) and K₂CO₃ (17.3 g, 0.125 mol) in a MeOH/H₂O mixture (200/50 mL). After stirring at room temperature for 30 min, glacial acetic acid was added until reaching a pH equal to 4 and the reaction mixture was stirred at 125° C. overnight. After concentration under vacuum, 300 mL of water were added and the resulting mixture was stirred and filtered. The water phase was extracted with 500 mL of CH₂Cl₂ and the filtered cake was dissolved in the CH₂Cl₂ layer. Then the CH₂Cl₂ layer was successively washed with 500 ml of water, saturated NaHCO₃ and brine, dried over MgSO₄ and concentrated, leading to 60 g of crude yellow solid.

The crude was purified by silica gel column chromatography (petroleum ether, petroleum ether/ethyl acetate 20/1). The resulting brown solid was further purified by recrystallization in a CH₂Cl₂/petroleum ether mixture (200/500 mL). After cooling in an acetone-CO₂ bath for 1 h, the precipitate was filtered and washed with cold petroleum ether leading to 55 g of the pure desired product (HPLC-MS purity ≧99%).

¹H NMR (400 MHz, CD₂Cl₂) δ 7.77 (s, 1H), 7.35 (d, J=8.8 Hz, 2H), 7.11 (d, J=8.8 Hz, 2H), 6.88 (s, 2H), 6.31 (s, 1H), 2.31 (s, 3H), 1.95 (s, 6H).

m/z (ESI-MS+) calcd 341.06478 ([M+H]⁺) found 341.06485

### Step 3: Synthesis of 1-(4-ethynylphenyl)-5-mesityl-1H-pyrazole (3)

A mixture of 1-(4-bromophenyl)-5-mesityl-1H-pyrazole (55 g, 0.16 mol), trimethylsilylacetylene (160 g, 1.63 mol), dichloro-bis(triphenylphosphine)palladium(II) (5.67 g, 8.1 mmol) and copper iodide (1.54 g, 8.1 mmol) in triethylamine (1000 mL) was stirred at 60° C. under nitrogen atmosphere overnight. Then, addition of trimethylsilylacetylene (80 g, 0.81 mol), dichloro-bis(triphenylphosphine)palladium(II) (2.84 g, 4 mmol) and copper iodide (0.77 g, 4 mmol) was carried out and the resulting mixture was allowed to react in the same conditions overnight. Afterwards, the reaction was quenched with water and extracted with ethyl acetate. The combined organic layer was dried over MgSO₄, filtered and the filtrate was concentrated. The residue was dissolved in 800 mL of MeOH and 8 g of NaOH were added slowly. After 2 h stirring, the mixture was acidified to pH 2-3 and then filtered and the filtrate was concentrated.

The crude was purified by silica gel column chromatography (petroleum ether/ethyl acetate: 100/1→50/1→20/1) leading to two fractions, 31 and 14 g, with HPLC-MS purity respectively equal to 93 and 99%. The less pure fraction was further purified by recrystallization in a CH₂Cl₂/petroleum ether mixture (200 mL/100 mL). After being placed in the fridge overnight and cooled in an acetone-CO₂ bath, the precipitate was filtered and washed with petroleum ether, leading to 22 g of a yellow solid with HPLC-MS purity equal to 96%.

¹H NMR (300 MHz, CDCl₃) δ 7.77 (d, J=1.8 Hz, 1H), 7.40-7.32 (m, 2H), 7.23-7.15 (m, 2H), 6.88 (s, 2H), 6.31 (d, J=1.8 Hz, 1H), 3.06 (s, 1H), 2.31 (s, 3H), 1.95 (s, 6H).

m/z (ESI-MS+): 287.1530 [M+H]⁺.

### Step 4: Synthesis of 1,3-bis((4-(5-mesityl-1H-pyrazol-1-yl)phenyl)ethynyl)benzene (4)

19.67 g of 1,3-diiodobenzene (59.6 mmol), 1.14 g of copper iodide (6.0 mmol) and 300 mL of triethylamine were stirred at 60° C. under nitrogen atmosphere for 30 minutes. Then 35 g of 1-(4-ethynylphenyl)-5-mesityl-1H-pyrazole prepared as in step 3 (122 mmol) and 6.88 g of tetrakis(triphenylphosphyne)palladium(O) (6 mmol) were sequentially added and the resulting suspension was stirred at 60° C. under nitrogen atmosphere for overnight. The reaction mixture became a solid which was suspended in dichloromethane and washed with water. The aqueous layer was extracted with dichloromethane. The combined organic layer was dried over MgSO₄, filtered and the filtrate was concentrated under reduced pressure. The crude was purified by silica gel column chromatography (petroleum ether/CH₂Cl₂: 10/1, 5/1, 3/1, 1/1, 1/3) leading to 30 g of a yellow solid which were washed with ethylacetate leading finally to 28 g of the desired product (LC-MS purity 95%).

¹H NMR (400 MHz, CD₂Cl₂) δ 7.76 (d, J=1.6 Hz, 2H), 7.63 (s, 1H), 7.50-7.44 (m, 2H), 7.40 (d, J=8.6 Hz, 4H), 7.37-7.31 (m, 1H), 7.23 (d, J=8.6 Hz, 4H), 6.91 (s, 4H), 6.32 (d, J=1.6 Hz, 2H), 2.31 (s, 6H), 1.95 (s, 12H).

### Step 5: Synthesis of Ligand L37

15 g of 1,3-bis((4-(5-mesityl-1H-pyrazol-1-yl)phenyl)ethynyl)benzene (23 mmol) from step 4 were dissolved in 240 mL of tetrahydrofuran. 7 g of acetic acid (116 mmol) and 60 mL of methanol were successively added. After 30 min stirring, 30 g of palladium on activated charcoal (10 wt %) were added and the mixture was stirred under hydrogen (1 MPa) at 35° C., the reaction being monitored by LC-MS. After 3 d, the reaction mixture was filtered and the cake was washed with tetrahydrofuran. All organic layers were combined and concentrated. The residue was dissolved in CH₂Cl₂ and washed with saturated NaHCO₃ and brine, dried over MgSO₄, filtered and concentrated. The so obtained white solid was combined with two other samples recovered from two batches performed in the same conditions and starting from 15 and 7 g of 1,3-bis((4-(5-mesityl-1H-pyrazol-1-yl)phenyl)ethynyl)benzene. The resulting solid mixture was poured into ethylacetate and stirred overnight. It was then filtered and washed with petroleum ether, leading finally to 27 g of the desired ligand L37 as confirmed by NMR and LC-MS analysis (HPLC purity >98%).

¹H NMR (400 MHz, CD₂Cl₂) δ 7.69 (d, J=1.7 Hz, 2H), 7.16-7.08 (m, 5H), 7.01 (d, J=8.5 Hz, 4H), 6.95-6.81 (m, 7H), 6.27 (d, J=1.7 Hz, 2H), 2.81 (s, 8H), 2.27 (s, 6H), 1.99-1.88 (m, 12H) m/z (ESI-MS+): 655.3796 [M+H]⁺.

### b) Complex IV Synthesis A: Reaction of Ir(Acac)₃ with a Mixture of Tetradentate Ligand L37 and Additional Bidentate Ligand L′₁

0.514 g of tetradentate ligand L37 (0.78 mmol), 0.244 g of 1-(2,6-diisopropylphenyl)-2-phenyl-1H-imidazole additional bidentate ligand L′₁ (0.80 mmol) and 0.38 g of Ir(acac)₃ (0.78 mmol) were introduced in a amber 10 mL vial which was subsequently evacuated and backfilled with argon. The vial was then heated under stirring up to 240° C. for 48 h in a sand bath. After cooling, the resulting solid was dissolved in CH₂Cl₂ and purified by silica gel column chromatography using CH₂Cl₂/hexane 8:2 (v/v) as the eluent to yield 0.054 g of complex IV as confirmed by 1H-NMR and LC-MS analysis. No other product than hexane could be detected by ¹H-NMR analysis (NMR purity using octamethylcyclotetrasiloxane as internal standard: 92 wt %).

### c) Complex IV Synthesis B: Reaction Between Dimer [(L′₁)₂Ir(μ-Cl)₂Ir(L′₁)₂] and Tetradentate Ligand L37

0.200 g of the dimer [(L′₁)₂Ir(μ-Cl)₂Ir(L′₁)₂] from example 1 and 0.386 g of tetradentate ligand L37 were introduced into a 50 mL vial flushed with argon. 24 mL of a solvent mixture of diglyme and water of 1:1 volume ratio was poured into the vial under argon. After being sealed, the vial was heated under stirring at 130° C. for 144 h. After cooling, the precipitate was filtered off with suction and washed with water and hexane. The resulting solid was dissolved in CH₂Cl₂ and purified by silica gel column chromatography using CH₂Cl₂/hexane 8:2 (v/v) as the eluent to yield 0.037 g of complex IV as confirmed by 1H-NMR and LC-MS analysis. Yield based on iridium metal: 14%. No other product could be detected by ¹H-NMR analysis (NMR purity using octamethylcyclotetrasiloxane as internal standard: 99 wt %).

λₘₐₓ emission (nm) in 2-MetTHF solutions (10⁻⁵ M) at room temperature: 461, 492 (max)

### EXAMPLE 5

Synthesis of complex V (formula hereafter) wherein the bidentate ligand units L of the symmetric tetradentate ligand pertain to general formula (12) while the additional bidentate ligand L′ corresponds to a cyclometallated ĈC ligand which means that it is bound to the iridium metal via a neutral donor atom which is a carbon in the form of a carbene and through a carbon atom having formally a negative charge. More specifically, the symmetric tetradentate ligand corresponds to ligand of formula (L37) wherein the bidentate ligand units L pertain to formula (23) and the additional bidentate ligand L′ corresponds to the ĈC ligand L′₃ from example 3.

As in example 3, the bidentate ligand units L of the symmetric tetradentate ligand correspond to cyclometallated ĈN ligands while the additional bidentate ligand L′ corresponds to a cyclometallated ĈC ligand.

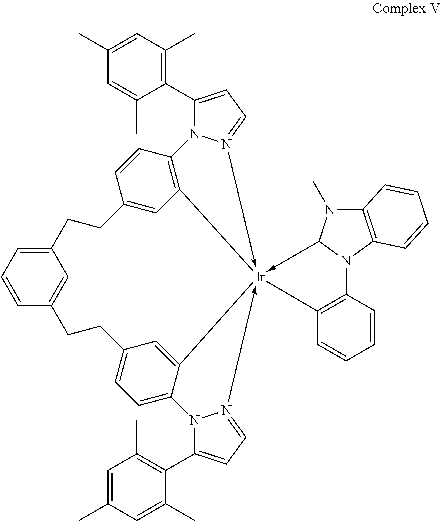

### Synthesis of Complex V

0.075 g of tetradentate ligand L37 (0.12 mmol; 1.1 eq.) was dissolved in toluene (75 mL) and the solution was degassed by nitrogen bubbling for 30 minutes. After this time, the iridium carbene precursor complex from example 3 (52 mg; 0.095 mmol; 1 eq.) and AgOAc (19 mg; 0.115 mmol; 1.2 eq.) were added and the flask subjected to three rapid nitrogen-vacuum-nitrogen cycles. The reaction mixture was refluxed under nitrogen in darkness for 4 days. After this time, the solvent was removed in vacuo and the residue purified rapidly by column chromatography in darkness (protected with aluminium foil) on neutral alumina, eluting cyclohexane. It was obtained mainly a mixture of two isomers, which one of them was possible to isolate.

Fraction 2=Yield: ˜37 mg. Mixture of isomers

Fraction 3=Yield: ˜3 mg. ¹H NMR (400 MHz, CD₂Cl₂) δ 8.11 (d, J=7.9 Hz, 1H), 7.68 (t, J=13.7 Hz, 1H), 7.30 (s, 3H), 7.15 (d, J=11.3 Hz, 2H), 7.09-6.84 (m, 6H), 6.77 (t, J=11.1 Hz, 1H), 6.63-6.47 (m, 3H), 6.41-6.21 (m, 4H), 6.14 (d, J=6.9 Hz, 2H), 6.00 (d, J=21.7 Hz, 1H), 5.81 (d, J=21.9 Hz, 1H), 5.61 (d, J=18.6 Hz, 1H), 3.47 (s, 3H), 2.88 (d, J=33.0 Hz, 2H), 2.67 (d, J=33.3 Hz, 2H), 2.49-2.24 (m, 10H), 2.10 (s, 3H), 2.01 (s, 3H), 1.85 (s, 3H), 1.77 (s, 3H)

m/z (MALDI-MS) calcd. 1053.420 ([M+H]⁺) found 1053.389.

### EXAMPLE 6

Synthesis of complex VI (formula hereafter) wherein the bidentate ligand units L of the symmetric tetradentate ligand pertain to general formula (12) while the additional bidentate ligand L′ corresponds to a “classical” ancillary ligand. More specifically, the symmetric tetradentate ligand corresponds to ligand of formula (L37) wherein the bidentate ligand units L pertain to formula (23) and the additional bidentate ligand L′ corresponds to the tetrakispyrazolylborate ancillary ligand.

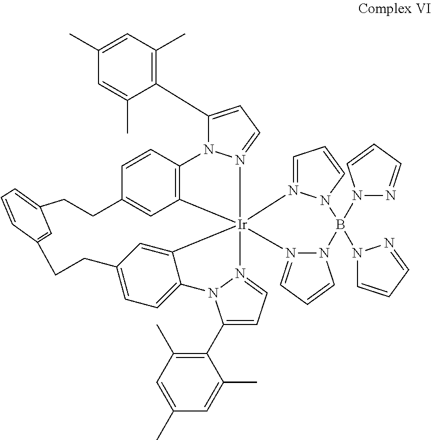

### Synthesis of Complex VI

1^{st} step: A suspension of tetradentate ligand L37 (0.94 mmol) and iridium trichloride monohydrate (0.299 g, 0.94 mmol) in a mixture of ethoxyethanol/water (3:1 v/v, 40 mL) was stirred at 140° C. under nitrogen atmosphere overnight. Then, the reaction mixture was allowed to cool down to room temperature and water was added. The resulting suspension was filtered and the solid was sequentially washed with water, methanol and ether. The obtained solid was suspended in a mixture of dichloromethane/methanol (4:1), filtered through a Celite pad and the filtrate was concentrated. The solid residue was suspended in dichloromethane/ether and filtered. The resulting solid was washed with ether and dried in the air, obtaining 0.204 g of a pale grey solid. The filtrate was concentrated obtaining 0.483 g of a yellow solid which was used in the next step without further purification.

2^{nd} step: Silver triflate (0.088 g, 0.34 mmol) was added to a solution of the dimer precursor (0.242 g, 0.14 mmol) in dichloromethane/methanol (1:1, 14 mL) and the reaction mixture was stirred at room temperature and protected from light for three hours. Then, the resulting suspension was centrifuged and the supernatant solution was concentrated. The obtained yellowish oil was dissolved in acetonitrile (10 mL) and potassium tetrapyrazolyl borate (0.175 g, 0.55 mmol) was added. The resulting suspension was refluxed under nitrogen atmosphere overnight. Subsequently the reaction mixture was allowed to cool down to room temperature, concentrated and the solid residue was suspended in dichloromethane and filtered. The filtrate was concentrated and the resulting crude oil was purified by flash column chromatography using as eluent mixtures of dichloromethane/acetone (ratios: 1:0, 70:1, 50:1, 30:1, 20:1 and 10:1) leading to 0.05 g of the pure target complex VI as confirmed by NMR analysis and electrospray ionization mass spectrometry.

¹H NMR (300 MHz, CDCl₃) δ 7.79 (d, J=1.1 Hz, 2H), 7.45 (d, J=1.1 Hz, 2H), 7.23 (d, J=1.9 Hz, 2H), 6.97 (d, J=10.6 Hz, 4H), 6.95-6.84 (m, 2H), 6.75-6.67 (m, 2H), 6.50 (d, J=1.9 Hz, 2H), 6.33 (d, J=1.9 Hz, 2H), 6.26-6.22 (m, 2H), 6.19 (d, J=1.4 Hz, 2H), 6.16-6.12 (m, 2H), 6.06-5.99 (m, 4H), 5.92 (dd, J=8.2, 1.6 Hz, 2H), 3.95 (m, 1H), 2.85-273 (m, 2H), 2.57-2.45 (m, 2H), 2.34 (s, 6H), 2.17 (s, 6H), 2.15 (s, 2H), 2.13-2.09 (m, 1H), 1.86 (s, 6H).

¹¹B NMR (96 MHz, CDCl₃) δ 1.40 (s).

m/z (ESI-MS+): 1125.45654 [M+H]⁺.

### 3°) Synthesis of Ir(III) Complexes Wherein the Bidentate Ligand Units L of the Symmetric Tetradentate Ligand Pertain to General Formula (10) and More Particularly to General Formula (29)

### EXAMPLE 7

Synthesis of complex VII (formula hereafter) wherein the bidentate ligand units L of the symmetric tetradentate ligand pertain to general formula (29) while the additional bidentate ligand L′ pertains to general formula (9). More specifically, the symmetric tetradentate ligand corresponds to ligand of formula 51 (see hereafter) and the additional bidentate ligand L′ corresponds to a NAN ligand which means that it is bound to the iridium metal via a neutral donor nitrogen atom and through a nitrogen atom having formally a negative charge.

In this case, the bidentate ligand units L of the symmetric tetradentate ligand correspond to cyclometallated CAN ligands while the additional bidentate ligand L′ corresponds to a NAN ligand.

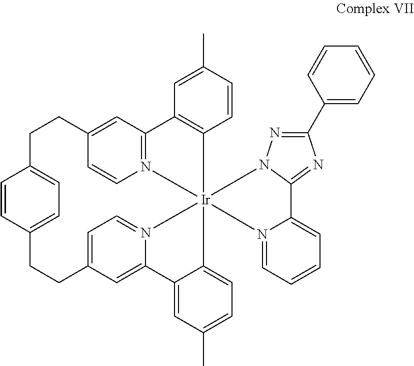

### a) Synthesis of Symmetric Tetradentate Ligand L51

The bidentate ligand units L of the symmetric tetradentate ligand L51 pertain to general formula (10) and more specifically to formula (29); the central scaffold A is a phenyl ring and both pending arms units B¹ and B² are —CH₂—CH₂— units linked in para positions to each other on the A phenyl ring.

The ligand L51 was synthesized according to the following scheme:

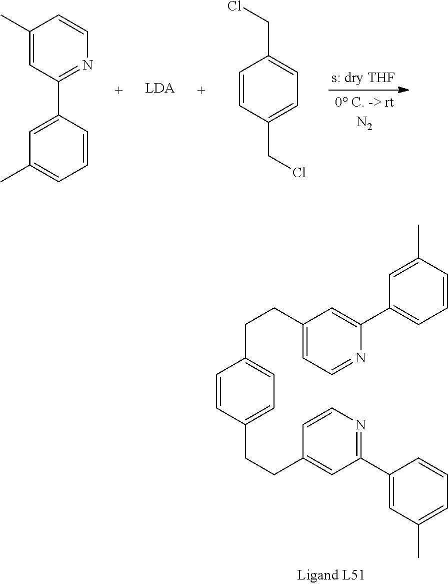 [SMILES: Cc1cccc(-c2cc(C)ccn2)c1 ; ClCc1ccc(CCl)cc1 ; Cc1cccc(-c2cc(CCc3ccc(CCc4ccnc(-c5cccc(C)c5)c4)cc3)ccn2)c1]

0.78 g (4.26 mmol) of 4-methyl-2-m-tolylpyridine was placed in a flame dried Schlenk flask. It was evacuated and refilled with nitrogen three times. Dry THF (15 mL) was then added and the flask was placed in an ice bath. 2.83 mL (4.25 mmol) of a 1.5 M solution of lithium diisopropylamide were added dropwise. The solution was stirred at this temperature for 1.5 h. A solution of 0.37 g (2.1 mmol) of 1,4-bis(chloromethyl)benzene in THF was prepared in a second flask under nitrogen. It was then added dropwise to the first solution and the mixture was stirred at ambient temperature over night. Water was added to quench the reaction. After extraction between ethylacetate and water the organic layer was dried over MgSO₄, dried and filtered. After removal of the solvent the crude compound was purified by column chromatography on SiO₂ with hexane/EtOAc 7:3 to get the desired product as a white solid as confirmed by 1H-NMR and electrospray ionization mass spectrometry. Yield: 0.65 g.

¹H NMR (300 MHz, CDCl₃) δ 8.47 (dd, J=5.0, 0.6 Hz, 2H), 7.71 (s, 2H), 7.62 (d, J=7.7 Hz, 2H), 7.39 (d, J=0.6 Hz, 2H), 7.26 (t, J=7.6 Hz, 2H), 7.21-7.09 (m, 2H), 7.01 (s, 4H), 6.93 (dd, J=5.1, 1.6 Hz, 2H), 2.86 (s, 8H), 2.34 (s, 6H)

m/z (ESI-MS+) calcd 469.2638 ([M+H]⁺) found 469.2638,

### b) Synthesis of Complex VII

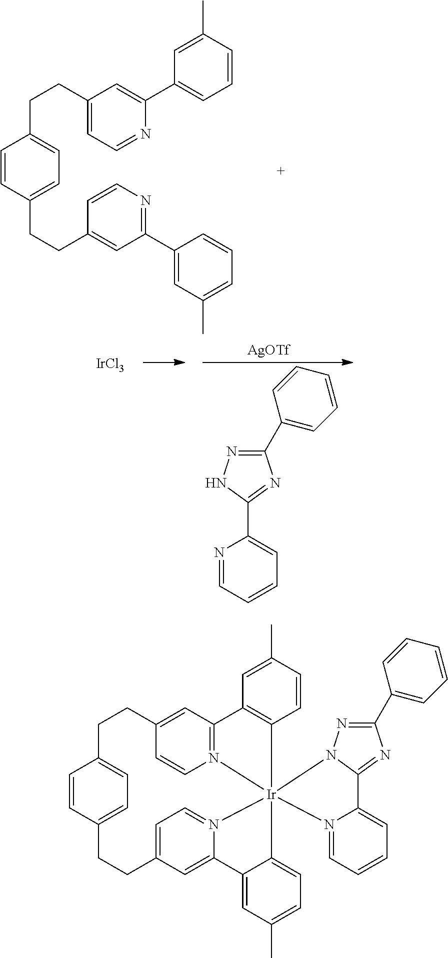

0.5 g (1.07 mmol) of tetradentate ligand L51 and 0.38 g (1.07 mmol) of IrCl₃.xH₂O were heated to 120° C. in 2-ethoxyethanol under nitrogen over night. After cooling to room temperature, water was added to induce precipitation. The precipitate was filtered off and air-dried. 0.64 g of a yellow powder was obtained, that was used without further purification. 0.37 g (0.27 mmol) of this precursor was suspended in acetone. 0.14 g (0.53 mmol) of silver triflate were added. After being stirred at 50° C. in the dark over night, the mixture was filtered and the solvent removed. The residue was redissolved in butanone. 0.12 g (0.53 mmol) of 2-(3-phenyl-1H-1,2,4-triazol-5-yl)pyridine L′₄ ligand was added and the solution heated to 80° C. over night. After removal of the solvent, the crude compound was purified by column chromatography on silica gel with CH₂Cl₂/MeOH 5% as eluent to get 30 mg of a bright yellow powder of the desired complex as confirmed by 1H-NMR and MALDI-TOF mass spectrometry.

H NMR (400 MHz, CDCl3) δ 8.71 (s, 1H), 8.36-8.1 (m, 4H), 7.95-7.62 (m, 4H), 7.6-7.28 (m, 9H), 7.2-7.1 (s, 1H), 7.1-6.7 (d, 5H), 6.7-6.5 (d, 1H), 3.28-1.15 (m, 14H)

m/z (MALDI) calcd. 881.08 ([M+H]⁺) found 881.16

λₘₐₓ emission (nm) in CHCl₃ solution at room temperature: 500 nm

### EXAMPLE 8

Synthesis of complex VIII (formula hereafter) wherein the bidentate ligand units L of the symmetric tetradentate ligand pertain to general formula (29) while the additional bidentate ligand L′ pertains to general formula (9). More specifically, the symmetric tetradentate ligand corresponds to ligand of formula 52 (see hereafter) and the additional bidentate ligand L′ corresponds to a NAN ligand which means that it is bound to the iridium metal via a neutral donor nitrogen atom and through a nitrogen atom having formally a negative charge.

As in example 7, the bidentate ligand units L of the symmetric tetradentate ligand correspond to cyclometallated ĈN ligands while the additional bidentate ligand L′ corresponds to a N̂N ligand

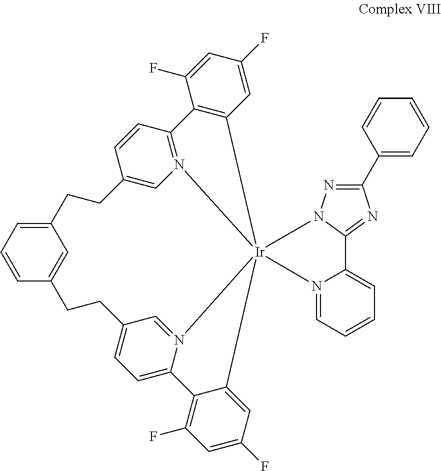

### a) Synthesis of Symmetric Tetradentate Ligand L52

The bidentate ligand units L of symmetric tetradentate ligand L52 pertain to general formula (10) and more specifically to formula (29); the central scaffold A is a phenyl ring and both pending arms units B¹ and B² are —CH₂—CH₂— units linked in meta positions to each other on the A phenyl ring.

The ligand L52 was synthesized according to the following scheme:

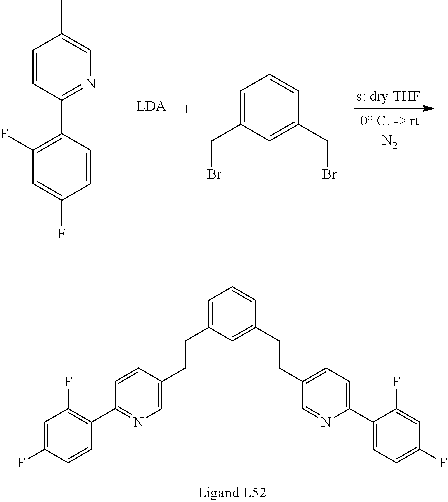 [SMILES: Cc1ccc(-c2ccc(F)cc2F)nc1 ; BrCc1cccc(CBr)c1 ; Fc1ccc(-c2ccc(CCc3cccc(CCc4ccc(-c5ccc(F)cc5F)nc4)c3)cn2)c(F)c1]

2.85 g (13.9 mmol) of 2-(2,4-difluorophenyl)-5-methylpyridine were dissolved in 20 mL of dry THF. The solution was degassed by several cycles of evacuation and refilling with Ar. It was cooled to −78° C. 9.7 mL of a 1.5 M solution of LDA in hexane were added dropwise. It was kept at this temperature for 1.5 h after which 1.75 g (6.6 mmol) of 1,3-di-(bromomethyl)benzene were added as a solid. After stirring at this temperature for another 30 min, the cooling bath was removed and the solution was let warm up to room temperature over night. It was extracted between CH₂Cl₂ and brine, the organic phase dried over magnesium sulfate and filtered. After removal of the solvent, the crude product was purified by column chromatography on silica gel using cyclohexane/ethylacetate 7:3 as the eluent to get the desired product as a colorless oil as confirmed by 1H-NMR analysis. Yield: 1.64 g.

H NMR (400 MHz, CDCl₃) δ 8.54 (s, 2H), 7.86-7.7 (q, 2H), 7.66-7.46 (dd, 4H), 7.34-6.81 (m, 8H), 2.39 (s, 8H)

### b) Synthesis of Complex VIII

1.16 g (2.26 mmol) of tetradentate ligand L52 and 0.8 g (2.26 mmol) of IrCl₃.xH₂O were heated at 120° C. in 2-ethoxyethanol over night. After cooling to room temperature, water was added to induce precipitation. The solid was filtered off and air-dried. The obtained yellow powder was used without further purification.

1.2 g (0.81 mmol) of this precursor was placed in a round bottom flask.

400 mL of a CH₂Cl₂/acetone mixture 1:1 were added, but the starting material didn't dissolve completely. It was heated to 40° C. over night. The next day 0.9 g of 2-(3-phenyl-1H-1,2,4-triazol-5-yl)pyridine (4.05 mmol) were added, followed by the addition of triethylamine (0.41 g, 0.56 mL). The reaction mixture was heated to 40° C. over night. After removal of the solvent, the crude product was purified by column chromatography on silica gel using CH₂Cl₂/MeOH 3% as the eluent. The compound was obtained as a mixture of isomers as confirmed by 1H-NMR and MALDI-TOF mass spectrometry.

m/z (MALDI) calcd 924.98 ([M+H]⁺) found 925.28.

λₘₐₓ emission (nm) in CHCl₃ solution at room temperature: 477 nm

1. A light-emitting transition metal complex comprising a transition metal M with a coordination number of six and an atomic number of at least 40 and a subunit with a symmetric tetradentate ligand comprising two identical bidentate ligand units L and represented by general formula (1) 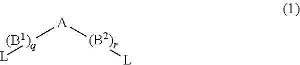
wherein q and r are 0 or 1, the pending arms B¹ and B² which may be the same or different, are represented by general formula (2) 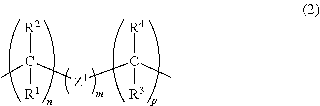
wherein Z¹ is a divalent group selected from the group consisting of
—O—, —S—, —NR^{S}—, —BR⁶—, —P(═O)R⁸—, —SiR⁹R¹⁰—, —N(R¹¹)—C(═O)—,
—N═C(R¹²)—, —C(═O)—, —C═NR¹³—, —C(═S)— and —P(═S)(R¹⁴)—,
wherein R¹ to R¹⁴, which may be the same or different at each occurrence, are selected from hydrogen, halogen, NO₂, CN, NH₂, NHR′, N(R′)₂, B(OH)₂, B(OR′)₂, CHO, COOH, CONH₂, CON(R′)₂, CONHR′, SO₃H, C(═O)R′, P(═O)(R′)₂, S(═O)R′, S(═O)₂R′, P(R′)₃⁺, N(R′)₃⁺, OH, OR′, SR′ and alkyl, haloalkyl, aralkyl, aryl or heteroaryl groups with R′ being selected from hydrogen, alkyl, aralkyl, aryl and heteroaryl groups, and
n, m and p, independently of one another, are integers of from 0 to 8, the sum of n, m and p being at least 1 and
wherein the ligand unit L is represented by formula (3) 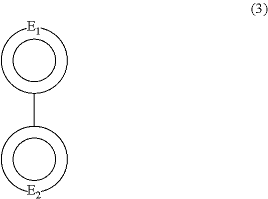
wherein
E₁ represents a nonmetallic atom group required to form a 5- or 6-membered heteroaromatic ring, optionally condensed with additional aromatic moieties or non aromatic cycles, said ring optionally having one or more substituents, optionally forming a condensed structure with the ring comprising E₂, and
E₂ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E₁, and
wherein the ring E1 is bound to the transition metal via a neutral heteroatom and the ring E2 is bound to the transition metal through a carbon atom having formally a negative charge or through a nitrogen atom having formally a negative charge and with the proviso that L is not 2-phenylpyridine and wherein
central scaffold A is a bivalent linking group selected from the group consisting of general formulae (4) to (7) 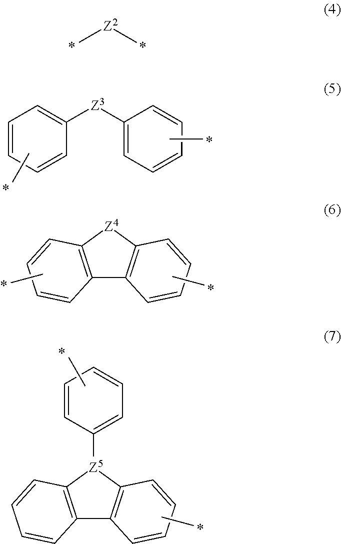
wherein the rings in formulae (5) to (7) may be unsubstituted or substituted by substituents R,
Z² is CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te or a substituted or unsubstituted 5- or 6-membered carbocyclic, aromatic or heteroaromatic ring,
Z³ and Z⁴ are CR₂, NR, R₂N⁺, RB, R₂B⁻, RP, RP(O), SiR₂, RAl, R₂Al⁻, RAs, RAs(O), RSb, RSb(O), RBi, RBi(O), O, S, Se or Te,
Z⁵ is CR, N, RN⁺, B, RB⁻, P, P(O), SiR, Al, RAl⁻, As, As(O), Sb, Sb(O), Bi, Bi(O), and R, which may be the same or different at each occurrence, is selected from the group consisting of hydrogen, alkyl, haloalkyl, aralkyl, aryl and heteroaryl.

2. The light-emitting transition metal complex in accordance with claim 1 wherein the transition metal M is selected from the group consisting of Rh, Os, Re, Ir or Ru.

3. The light-emitting transition metal complex in accordance with claim 1, wherein Z², Z³ and Z⁴ are selected from the group consisting of CR₂, RN, O, S, RB, RP, RP(═O), SiR₂ and wherein Z⁵ is CR, N, B, P, P(O) or SiR.

4. The light-emitting transition metal complex in accordance with claim 1, wherein Z² is selected from the group consisting of substituted or unsubstituted 5- or 6-membered carbocyclic, aromatic or heteroaromatic rings.

5. The light-emitting transition metal complex in accordance with claim 1, wherein the ligand unit L is represented by the formulas (8) to (10) 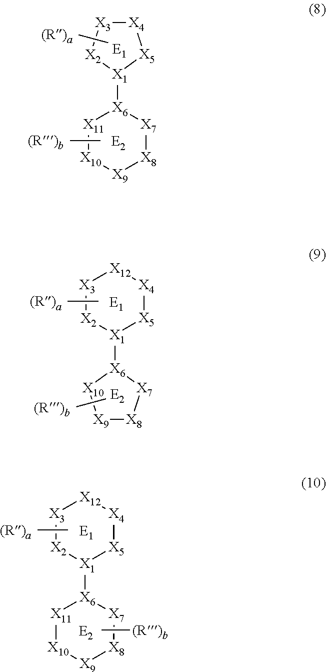
wherein
X₅ is a neutral nitrogen atom via which the 5- or 6-membered heteroaromatic ring E₁ is bonded to the metal,
X₇ is a carbon atom having formally a negative charge or a nitrogen atom having formally a negative charge via which the 5- or 6-membered aromatic or heteroaromatic ring E₂ is bonded to the metal,
X₁, X₂, X₃, X₄, X₆, X₈, X₉, X₁₀, X₁₁, X₁₂ are independently from one another a carbon or a heteroatom,
R″ and R′″, which may be the same or different at each occurrence, are hydrogen, halogen, NO₂, CN NH₂, NHR⁶¹, N(R⁶¹)₂, B(OH)₂, B(OR⁶¹)₂, CHO, COOH, CONH₂, CON(R⁶¹)₂, CONHR⁶¹, SO₃H, C(═O)R⁶¹, P(═O)(R⁶¹)₂, S(═O)R⁶¹, S(═O)₂R⁶¹, P(R⁶¹)₃⁺, N(R⁶¹)₃⁺, OR⁶¹, SR⁶¹, Si(R⁶¹)₃, a straight chain alkyl or alkoxy group having 1 to 20 carbon atoms or a branched or cyclic alkyl or alkoxy group with 3 to 20 carbon atoms, a haloalkyl group, a substituted or unsubstituted aromatic or heteroaromatic ring system having 5 to 50 ring atoms or a substituted or unsubstituted aryloxy, heteroaryloxy or heteroarylamino group having 5 to 50 ring atoms,
two or more substituents R″ and R′″, either on the same or on different rings may define a further mono- or polycyclic, aliphatic or aromatic ring system with one another or with a substituent R⁶¹,
R⁶¹, which may be the same or different on each occurrence, may be a straight chain alkyl or alkoxy group having 1 to 20 carbon atoms or a branched or cyclic alkyl or alkoxy group with 3 to 20 carbon atoms, a substituted or unsubstituted aromatic or heteroaromatic ring system having 5 to 50 ring atoms or a substituted or unsubstituted aryloxy, heteroaryloxy or heteroarylamino group having 5 to 50 ring atoms, and a and b, independently from one another represent an integer in the range of from 0 to 3.

6. The light-emitting transition metal complex in accordance with claim 5 wherein the ligand unit L is represented by formula (9).

7. The light-emitting transition metal complex in accordance with claim 5 wherein the ligand unit L is represented by formula (10).

8. The light-emitting transition metal complex in accordance with claim 1, wherein the ligand unit L is selected from the group consisting of phenylimidazole derivatives, phenylpyrazole derivatives, phenyltriazole derivatives, phenyltetrazole derivatives, 2-(1H-1,2,4-triazol-5-yl)pyridine derivatives, 2-(1H-pyrazol-5-yl)pyridine derivatives, phenylpyridine derivatives other than 2-phenylpyridine, phenylquinoline derivatives and phenylisoquinoline derivatives.

9. The light-emitting transition metal complex in accordance with claim 1 wherein the ligand unit L is selected from the group consisting of compounds of formulae (11) to (15) 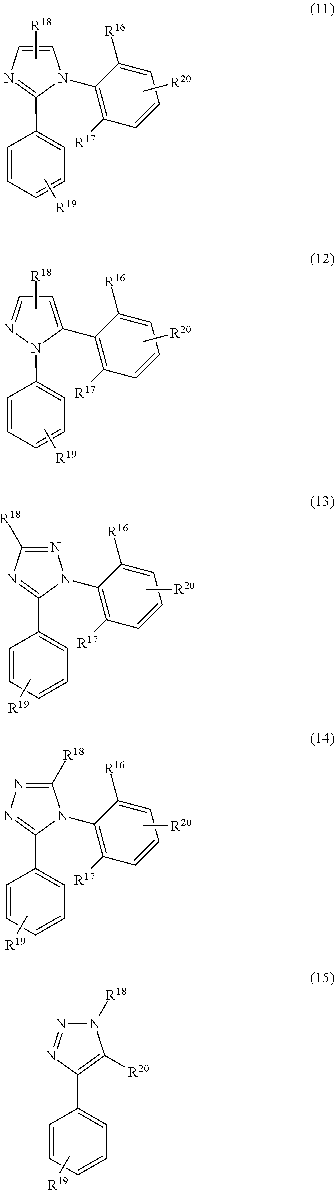
wherein R¹⁶ and R¹⁷ may be the same or different and are groups other than hydrogen selected from alkyl, haloalkyl, cycloalkyl, aryl and heteroaryl groups and wherein R¹⁸ to R²⁰ may be the same or different and may be selected from the group consisting of hydrogen, halogen, NO₂, CN, NH₂, NHR²¹, N(R²¹)₂, B(OH)₂, B(OR²¹)₂, CHO, COOH, CONH₂, CON(R²¹)₂, CONHR²¹, SO₃H, C(═O)R²¹, P(═O)(R²¹)₂, S(═O)R²¹, S(═O)₂R²¹, P(R²¹)₃⁺, N(R²¹)₃⁺, OH, OR²¹, SR²¹, Si(R²¹)₃, and alkyl, haloalkyl, alkenyl, alkynyl, arylalkyl, aryl and heteroaryl groups, with R²¹ being selected from hydrogen, alkyl, aralkyl, aryl and heteroaryl groups.

10. The light-emitting transition metal complex in accordance with claim 9 wherein the ligand unit L is selected from the group consisting of compounds of formulae (16) to (26) 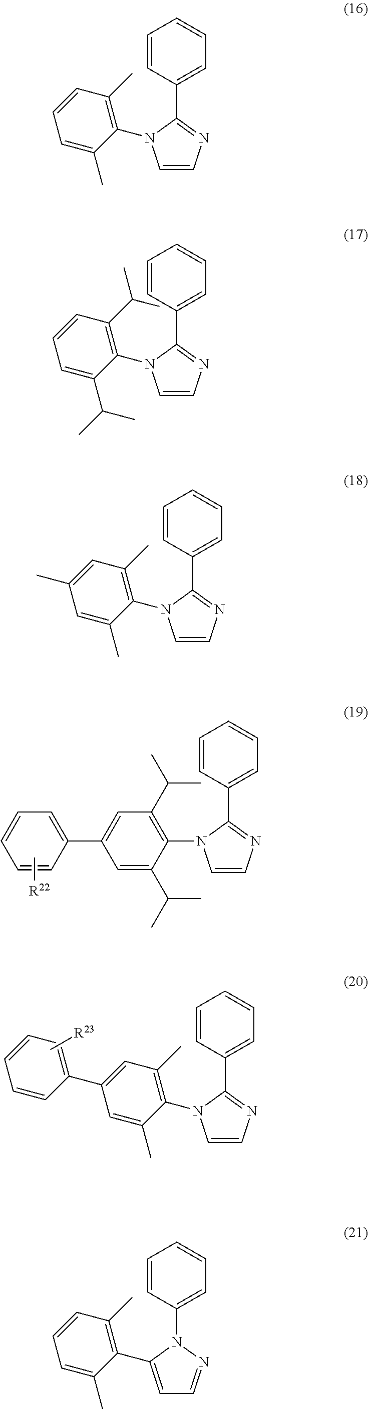 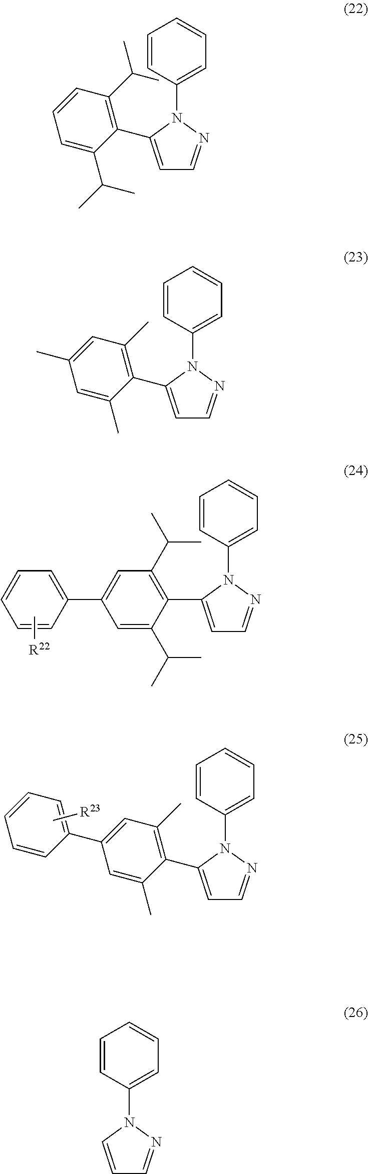
wherein R²² and R^{23′} independent of one another′ are selected from hydrogen, halogen, NO₂, CN, NH₂, NHR²⁴, N(R²⁴)₂, B(OH)₂, B(OR²⁴)₂, CHO, COOH, CONH₂, CON(R²⁴)₂, CONHR²⁴, SO₃H, C(═O)R²⁴, P(═O)(R²⁴)₂, S(═O)R²⁴, S(═O)₂R²⁴, P(R²⁴)₃⁺, N(R²⁴)₃⁺, OH, OR²⁴, SR²⁴, Si(R²⁴)₃, and alkyl, haloalkyl, alkenyl, alkynyl, arylalkyl, aryl and heteroaryl groups, with R²⁴ being selected from hydrogen, alkyl, aralkyl, aryl and heteroaryl groups.

11. The light-emitting transition metal complex in accordance with claim 1 wherein the ligand unit L is selected from compounds of formulae (27) to (28): 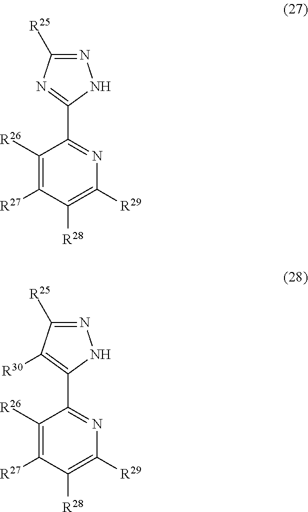
wherein R²⁵ to R³⁰ may be the same or different at each occurrence and may be selected from the group consisting of hydrogen, halogen, NO₂, CN, NH₂, NHR³¹, N(R³¹)₂, B(OH)₂, B(OR³¹)₂, CHO, COOH, CONH₂, CON(R³¹)₂, CONHR³¹, SO₃H, C(═O)R³¹, P(═O)(R³¹)₂, S(═O)R³¹, S(═O)₂R³¹, P(R³¹)₃⁺, N(R³¹)₃⁺, OH, OR³¹, SR³¹, Si(R³¹)₃, and alkyl, haloalkyl, alkenyl, alkynyl, arylalkyl, aryl and heteroaryl groups, with R³¹ being selected from hydrogen, alkyl, aralkyl, aryl and heteroaryl groups.

12. The light-emitting transition metal complex in accordance with claim 1 wherein the ligand unit L is selected from compounds of formulae (29) to (31): 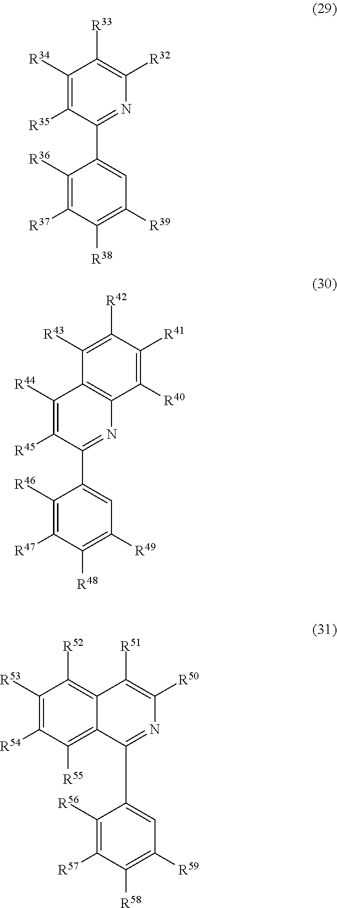
wherein R³² to R³⁹ may be the same or different at each occurrence and may be selected from the group consisting of hydrogen, halogen, NO₂, CN, NH₂, NHR⁶⁰, N(R⁶⁰)₂, B(OH)₂, B(OR⁶⁰)₂, CHO, COOH, CONH₂, CON(R⁶⁰)₂, CONHR⁶⁰, SO₃H, C(═O)R⁶⁰, P(═O)(R⁶⁰)₂, S(═O)R⁶⁰, S(═O)₂R⁶⁰, P(R⁶⁰)₃⁺, N(R⁶⁰)₃⁺, OH, OR⁶⁰, SR⁶⁰, Si(R⁶⁰)₃, and alkyl, haloalkyl, alkoxy, alkenyl, alkynyl, arylalkyl, aryl and heteroaryl groups, with R⁶⁰ being selected from hydrogen, alkyl, aralkyl, aryl and heteroaryl groups, provided that at least one of substituents R³² to R³⁹ is different from hydrogen, and
wherein R⁴⁰ to R⁵⁹ may be the same or different at each occurrence and may be selected from the group consisting of hydrogen, halogen, NO₂, CN, NH₂, NHR⁶⁰, N(R⁶⁰)₂, B(OH)₂, B(OR⁶⁰)₂, CHO, COOH, CONH₂, CON(R⁶⁰)₂, CONHR⁶⁰, SO₃H, C(═O)R⁶⁰, P(═O)(R⁶⁰)₂, S(═O)R⁶⁰, S(═O)₂R⁶⁰, P(R⁶⁰)₃⁺, N(R⁶⁰)₃⁺, OH, OR⁶⁰, SR⁶⁰, Si(R⁶⁰)₃, and alkyl, haloalkyl, alkoxy, alkenyl, alkynyl, arylalkyl, aryl and heteroaryl groups, with R⁶⁰ being selected from hydrogen, alkyl, aralkyl, aryl and heteroaryl groups.

13. The light-emitting transition metal complex in accordance with claim 1 wherein the tetradentate ligand is represented by any of formulas (L32) to (L45)

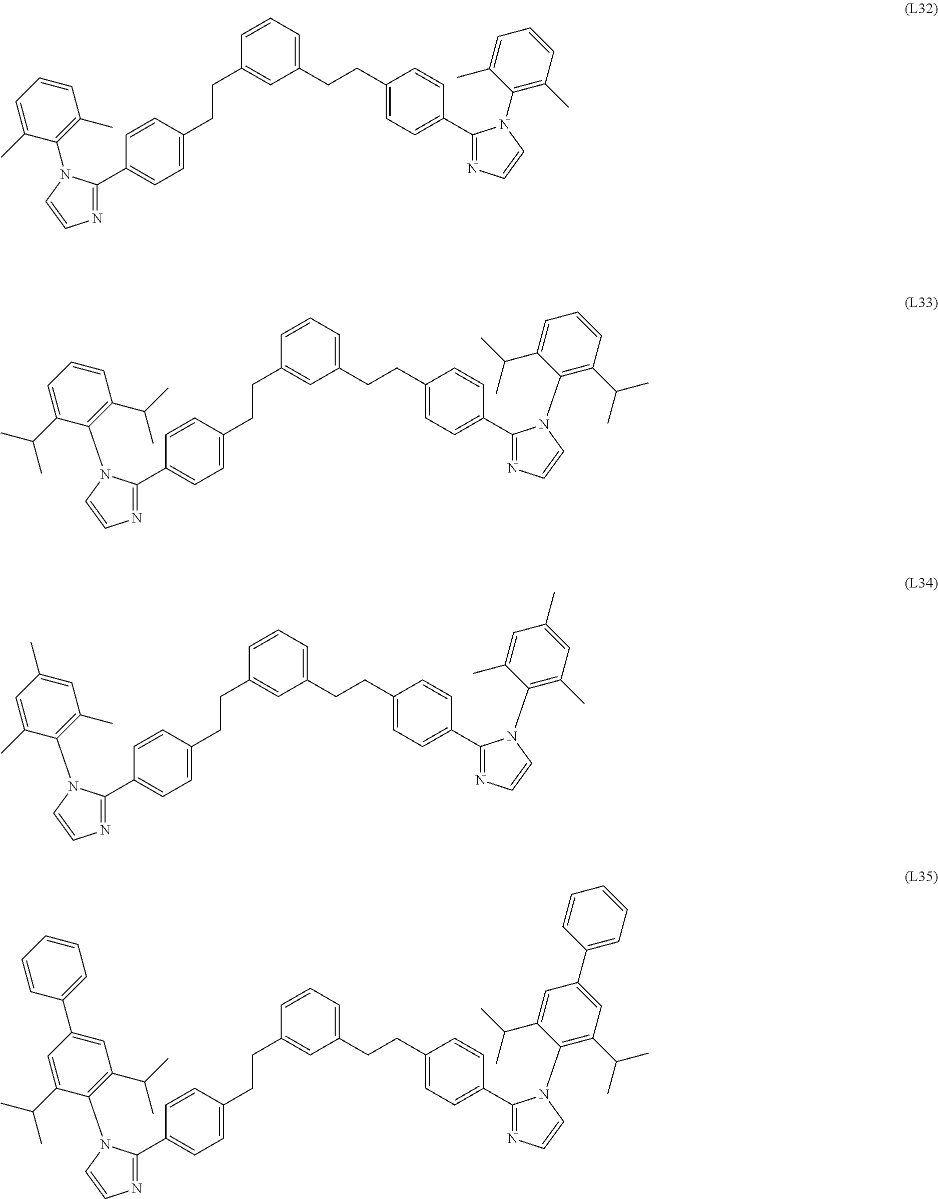

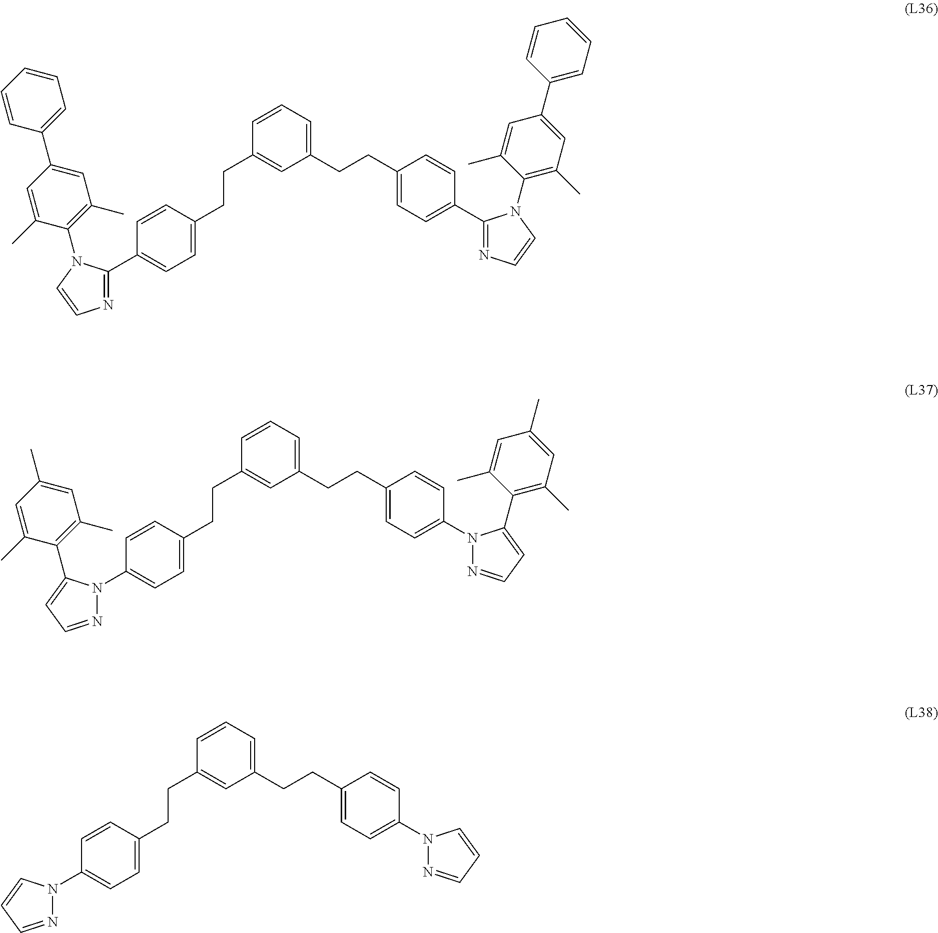

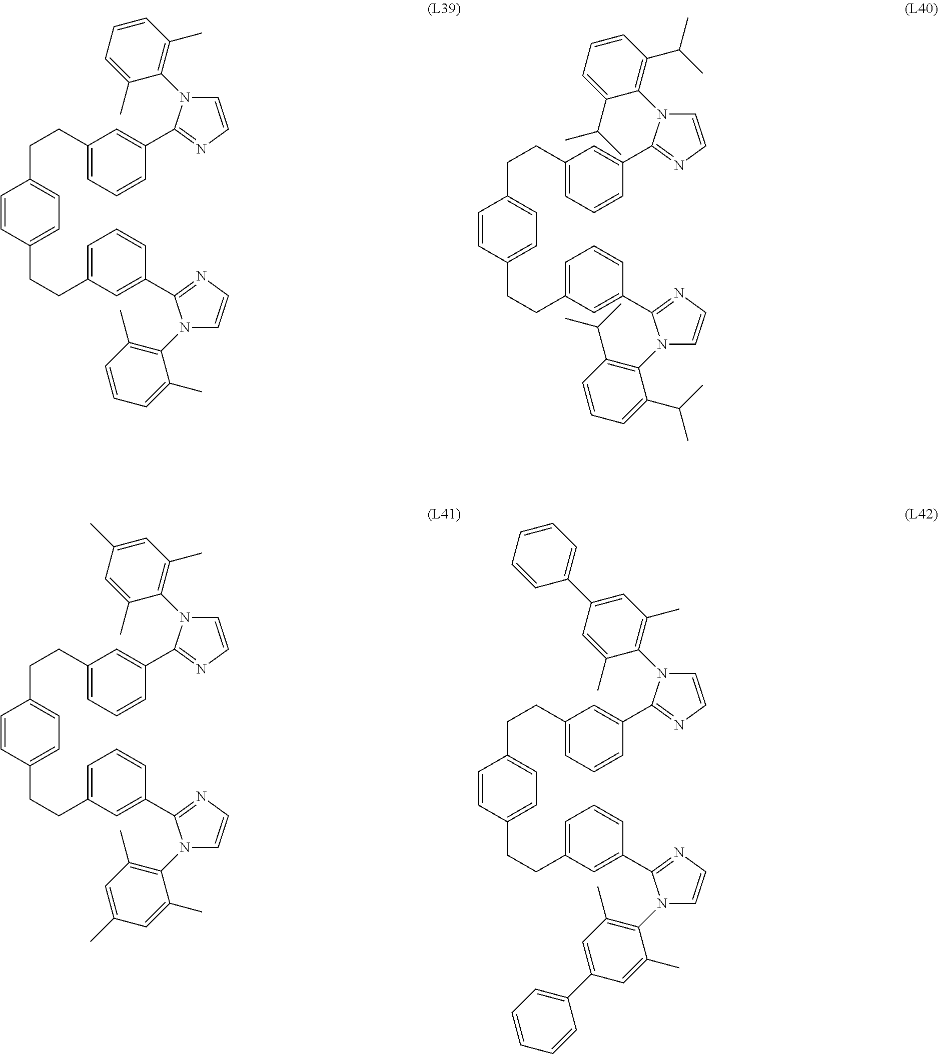 [SMILES: Cc1cccc(C)c1-n1ccnc1-c1cccc(CCc2ccc(CCc3cccc(-c4nccn4-c4c(C)cccc4C)c3)cc2)c1 ; CC(C)c1cccc(C(C)C)c1-n1ccnc1-c1cccc(CCc2ccc(CCc3cccc(-c4nccn4-c4c(C(C)C)cccc4C(C)C)c3)cc2)c1 ; Cc1cc(C)c(-n2ccnc2-c2cccc(CCc3ccc(CCc4cccc(-c5nccn5-c5c(C)cc(C)cc5C)c4)cc3)c2)c(C)c1 ; Cc1cc(-c2ccccc2)cc(C)c1-n1ccnc1-c1cccc(CCc2ccc(CCc3cccc(-c4nccn4-c4c(C)cc(-c5ccccc5)cc4C)c3)cc2)c1]

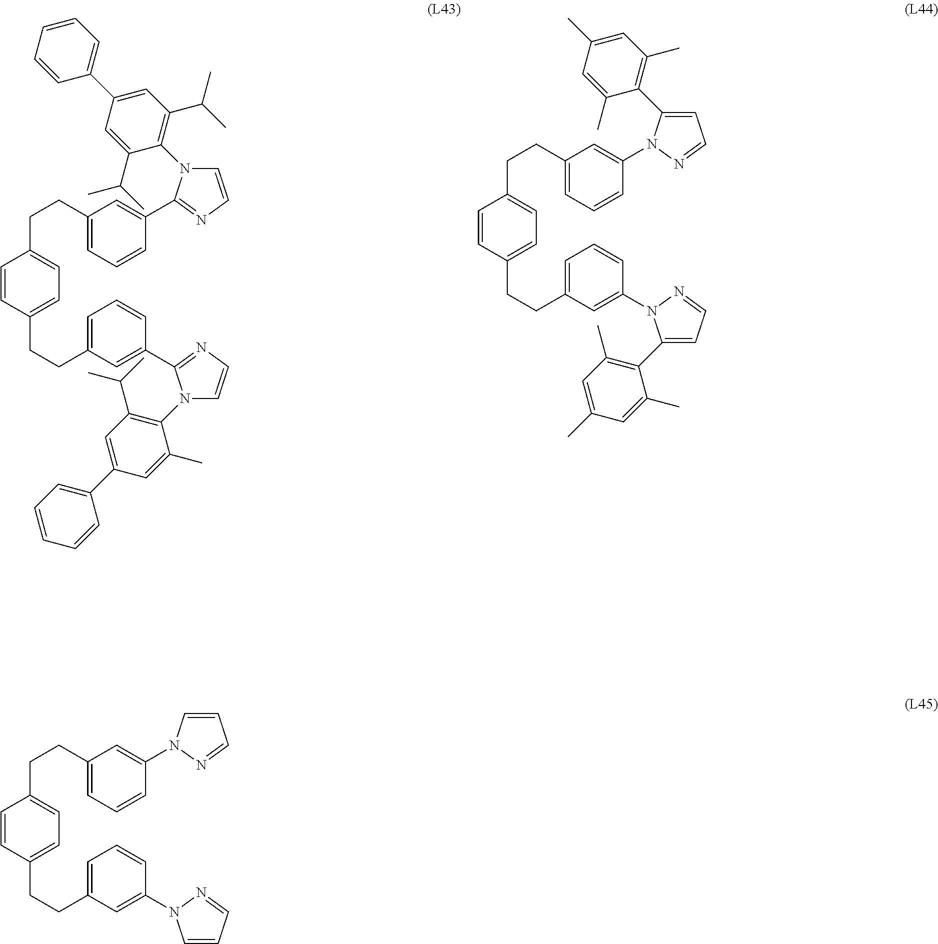 [SMILES: Cc1cc(-c2ccccc2)cc(C(C)C)c1-n1ccnc1-c1cccc(CCc2ccc(CCc3cccc(-c4nccn4-c4c(C(C)C)cc(-c5ccccc5)cc4C(C)C)c3)cc2)c1 ; Cc1cc(C)c(-c2ccnn2-c2cccc(CCc3ccc(CCc4cccc(-n5nccc5-c5c(C)cc(C)cc5C)c4)cc3)c2)c(C)c1 ; c1cc(CCc2ccc(CCc3cccc(-n4cccn4)c3)cc2)cc(-n2cccn2)c1]

14. The light-emitting transition metal complex in accordance with claim 1 comprising an additional bidentate ligand L′ selected from ligands of formula (3′) 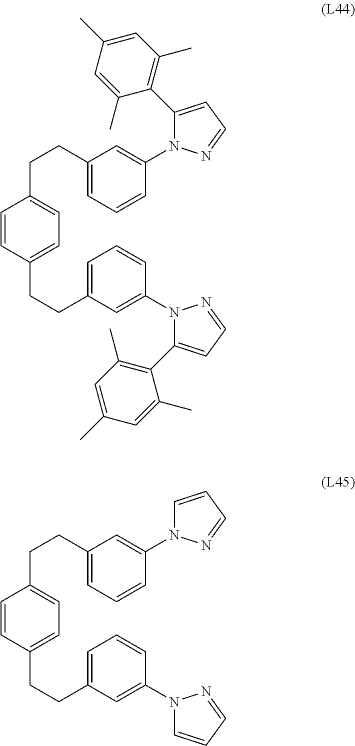
wherein
E′₁ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′₂, and
E′₂ represents a nonmetallic atom group required to form a 5- or 6-membered aromatic or heteroaromatic ring, optionally condensed with additional aromatic moieties or non aromatic cycles, said ring optionally having one or more substituents, optionally forming a condensed structure with the ring comprising E′₁, and
wherein the rings E′₁ and E′₂ could together form a polycyclic aliphatic, aromatic or heteroaromatic ring system and
wherein the ring E′₁ is bound to the transition metal via a neutral donor atom which is a carbon in the form of a carbene or a heteroatom and the ring E′₂ is bound to the transition metal through a carbon atom having formally a negative charge or through a nitrogen atom having formally a negative charge.

15. The light-emitting transition metal complex in accordance with claim 14 comprising an additional bidentate ligand L′ selected from formulae (8) to (31).

16. The light-emitting transition metal complex in accordance with claim 1 comprising an additional bidentate ligand L′ selected from ligands of general formulae E3-SBF, E3-Ar1-SBF, E3-Open SBF and/or E3-Ar1-Open SBF wherein
E3 is a 5-membered heteroaryl ring, bound to the metal atom by covalent or dative bonds and containing at least one donor nitrogen atom, wherein said heteroaryl ring may be un-substituted or substituted by substituents selected from the group consisting of halogen, alkyl, alkoxy, amino, cyano, alkenyl, alkynyl, arylalkyl, aryl and heteroaryl group and/or may form an annealed ring system with other rings selected from cycloalkyl, aryl and heteroaryl rings;
Ar1 when present is bound to the metal atom by covalent or dative bonds and is selected from the group consisting of substituted or un-substituted C₆-C₃₀ arylene and substituted or un-substituted C₂-C₃₀ heteroarylene group, which Ar1 group may be un-substituted or substituted by substituents selected from the group consisting of halogen, alkyl, alkoxy, amino, cyano, alkenyl, alkynyl, arylalkyl, aryl and heteroaryl groups;
SBF represents 9,9′-spirobifluorenyl, Open SBF represents 9,9-diphenyl-9H-fluorenyl, in both cases un-substituted or substituted by substituents selected from the group consisting of halogen, alkyl, alkoxy, amino, cyano, alkenyl, alkynyl, arylalkyl, aryl and heteroaryl groups or selected from picolinate, tetrakispyrazolylborate or acetylacetonate.

17. (canceled)

18. A layer suitable for forming the emissive layer of an organic light emitting device, said layer comprising a light emitting transition metal complex in accordance with claim 1 as dopant with a host material, wherein the amount of the light emitting transition metal complex with respect to the total weight of the host and the dopant is at most 35% wt.

19. A material with which an emissive layer of an organic light emitting device can be formed, said material comprising a light emitting transition metal complex in accordance with claim 1 as dopant with a host material wherein the amount of the light emitting transition metal complex with respect to the total weight of the host and the dopant is at most 35% wt.

20. An organic light-emitting device comprising an emissive layer (EML), said emissive layer comprising a light-emitting transition metal complex or mixture thereof in accordance with claim 1, optionally with a host material.

21. An organic light emitting device in accordance with claim 20 wherein the emissive layer comprises the host material, the light emitting transition metal complex is present as dopant with a host material and the amount of the light emitting transition metal complex with respect to the total weight of the host and the dopant is at most 35% wt.
